(19) United States
(12) Patent Application Publication
(10) Pub. No.: US 2024/0414956 A1
(43) Pub. Date: Dec. 12, 2024

(54) DISPLAY DEVICE

(71) Applicant: Samsung Display Co., Ltd., Yongin-Si (KR)

(72) Inventors: Jae Hyun LEE, Yongin-si (KR); Seung Ha CHOI, Yongin-si (KR); Ye Eun KANG, Yongin-si (KR); Jong Bum CHOI, Yongin-si (KR); Seung Rae KIM, Yongin-si (KR); Woo Geun LEE, Yongin-si (KR)

(21) Appl. No.: 18/398,197

(22) Filed: Dec. 28, 2023

(30) Foreign Application Priority Data
Jun. 7, 2023 (KR) 10-2023-0072708

(51) Int. Cl. H10K 59/123; G09G 3/32

(52) U.S. Cl. CPC H10K 59/123; G09G 3/32; G09G 2300/0842; H10K 59/122

(57) ABSTRACT

A display device includes a first pixel and a second pixel. The first pixel and the second pixel each includes a first transistor, a portion of a via layer disposed on the first transistor, and a portion of a first metal layer disposed on the via layer. The first pixel and the second pixel further include a first pixel electrode and a second pixel electrode disposed in the first metal layer, and a first end of the first pixel electrode faces the second pixel electrode and is positioned at a height lower than the second pixel electrode.

### CROSS-REFERENCE TO RELATED APPLICATION

This application claims priority from Korean Patent Application No. 10-2023-0072708 filed on Jun. 7, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of the Related Art

The importance of display devices has steadily increased with the development of multimedia technology. Accordingly, various types of display devices such as liquid crystal display (LCD) devices, organic light emitting diode (OLED) display devices and the like have been developed.

Among the display devices, a self-light emitting display device includes a self-light emitting element such as an organic light emitting element. The self-light emitting element may include two opposite electrodes and a light emitting layer interposed therebetween. The self-light emitting display devices are attracting attention as a next-generation display devices because of being able to meet the high display quality requirements such as wide viewing angle, high brightness and contrast, and quick response speed as well as being able to provide low power consumption, lightweight, and thin profiles since a separate power or light source such as a backlight unit is not required.

The self-light emitting display device may include various circuit layers for driving the light emitting layer. Such a circuit layer may be formed through one or more patterning processes using masks. As the number of masks and the number of layers constituting the circuit layer decrease, process efficiency may be improved. Also, a height difference or separation between the light emitting layer and a transistor for driving the light emitting layer may be reduced.

### SUMMARY

Aspects of the present disclosure provide a display device that reduces, minimizes, or prevents incidence of light emitted from a pixel onto a transistor within the pixel.

Aspects of the present disclosure also provide a display device that reduces, minimizes, or prevents light induced degradation of transistors.

Aspects of the present disclosure are not restricted to the specific examples set forth herein. The above and other aspects of the present disclosure will become more apparent to one of ordinary skill in the art to which the present disclosure pertains by referencing the detailed description given below.

According to an aspect of the present disclosure, a display device includes a first pixel and a second pixel, wherein the first pixel and a second pixel each include, a first transistor, a portion of a via layer disposed on the first transistor, and a portion of a first metal layer disposed on the via layer. The first pixel and the second pixel may further include a first pixel electrode and a second pixel electrode disposed on the first metal layer, respectively, and a first end, which is an end of the first pixel electrode, facing the second pixel electrode, is positioned at a height lower than the second pixel electrode.

In an embodiment, the via layer comprises a crest and a valley, a thickness of the crest is greater than a thickness of the valley, the first end is positioned on the valley, and the second pixel electrode is positioned on the crest.

In an embodiment, the thickness of the crest is 3 to 5 times the thickness of the valley.

In an embodiment, the via layer comprises a valley area, which is an area where the valley is positioned, and the valley area is disposed between the first transistor of the first pixel and the second pixel electrode in plan view.

In an embodiment, the display device may further comprise a pixel defining layer disposed on the first metal layer. The pixel defining layer comprises a plurality of open portions overlapping at least a part of the first pixel electrode and the second pixel electrode, and the open portions do not overlap the valley area.

In an embodiment, the open portions are disposed on the crest.

In an embodiment, the valley area is disposed to surround at least a portion of the first transistor of the first pixel in plan view.

In an embodiment, the valley area is disposed to surround a side of the first transistor of the first pixel in plan view, the side facing the second pixel electrode.

In an embodiment, the display device may further comprise a third pixel. The third pixel further comprises a third pixel electrode disposed in the first metal layer, and a second end, which is an end of the second pixel electrode, facing the third pixel electrode, is positioned at a height lower than the third pixel electrode.

In an embodiment, the valley area comprises a first region overlapping the first end, a second region overlapping the second end, and a third region connecting the first region to the second region.

In an embodiment, the first region is disposed to surround a side of the first transistor of the first pixel in plan view, the side facing the second pixel electrode.

In an embodiment, the second region is disposed between the third pixel electrode and a side of the first transistor of the second pixel in plan view, the side facing the third pixel electrode.

In an embodiment, the third region is disposed to surround a side of the first transistor of the second pixel in plan view, the side facing the first pixel electrode.

In an embodiment, the first region overlaps the first transistor of the first pixel.

In an embodiment, the valley area further comprises a fourth region protruding from the third region, and the fourth region is disposed between the first pixel electrode and the first transistor of the second pixel in plan view.

In an embodiment, each of the first pixel and the second pixel further comprises a first capacitor connected to the first transistor, and the first capacitor of each of the first pixel and the second pixel overlaps the crest.

In an embodiment, in a thickness direction of the via layer, no other metal layer is disposed between the first metal layer and the first transistor of the first pixel.

In an embodiment, each of the first pixel and the second pixel further comprising, a light emitting layer disposed on the first metal layer, and a second metal layer disposed on the light emitting layer, wherein the first transistor is a driving transistor configured to drive light emission of the light emitting layer.

According to an aspect of the present disclosure, there is provided a display device including a first pixel and a second pixel. The first pixel and the second pixel each includes a first transistor, a portion of a via layer disposed on the first transistor, and a portion of a first metal layer disposed on the via layer. The first pixel and the second pixel further include a first pixel electrode and a second pixel electrode disposed in the first metal layer, respectively, and a portion of the first pixel electrode overlapping the first transistor of the first pixel is positioned at a height lower than the second pixel electrode.

In an embodiment, a first end of the first pixel electrode facing the second pixel electrode is positioned at the same height as the second pixel electrode.

In an embodiment, the via layer comprises a crest and a valley, a thickness of the crest is greater than a thickness of the valley, a portion of the first pixel electrode overlapping the first transistor of the first pixel is positioned on the valley, and the second pixel electrode is positioned on the crest.

In an embodiment, in a thickness direction of the via layer, no other metal layer is disposed between the first metal layer and the first transistor of the first pixel.

In the display device according to one embodiment of the present disclosure, it is possible to reduce or minimize incidence of light emitted from an adjacent pixel onto a transistor within its own pixel.

In the display device according to one embodiment of the present disclosure, light induced degradation of a transistor may be reduced or minimized.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings.

FIG. 1 is a plan view illustrating a display device according to one embodiment.

FIG. 2 illustrates pixels and lines of a display device according to one embodiment.

FIG. 3 is an equivalent circuit diagram of a pixel according to one embodiment.

FIG. 4 is a layout diagram of a display panel according to one embodiment.

FIG. 5 is a cross-sectional view of a display panel according to a conventional embodiment.

FIG. 6 is a cross-sectional view taken along line X1-X1′ of FIG. 4.

FIG. 7 is a cross-sectional view taken along lines X2-X2′ and X3-X3′ of FIG. 4.

FIG. 8 is a cross-sectional view taken along line X4-X4′ of FIG. 4.

FIG. 9 is a plan view of a valley area according to one embodiment.

FIG. 10 is a layout diagram of a display panel according to another embodiment.

FIG. 11 is a cross-sectional view taken along line X5-X5′ of FIG. 10.

FIG. 12 is a plan view of a valley area according to another embodiment.

FIG. 13 is a layout diagram of a display panel according to another embodiment.

FIG. 14 is a cross-sectional view taken along line X6-X6′ of FIG. 13.

FIG. 15 is a plan view of a valley area according to another embodiment.

FIG. 16 is a layout diagram of a display panel according to another embodiment.

FIG. 17 is a cross-sectional view taken along line X7-X7′ of FIG. 16.

FIG. 18 is a plan view of a valley area according to another embodiment.

FIG. 19 is a layout diagram of a display panel according to another embodiment.

FIG. 20 is a cross-sectional view taken along line X8-X8′ of FIG. 19.

FIG. 21 is a layout diagram of a display panel according to another embodiment.

FIG. 22 is a layout diagram of a display panel according to another embodiment.

### DETAILED DESCRIPTION OF THE EMBODIMENTS

Embodiments of the present disclosure will now be described more fully hereinafter with reference to the accompanying drawings. The present invention may, however, be embodied in different forms and should not be construed as limited to the embodiments set forth herein. Rather, these embodiments are provided so that this disclosure will be thorough and complete and will fully convey the disclosed subject matter to those skilled in the art.

It will be understood in the following that when a layer or other structure is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

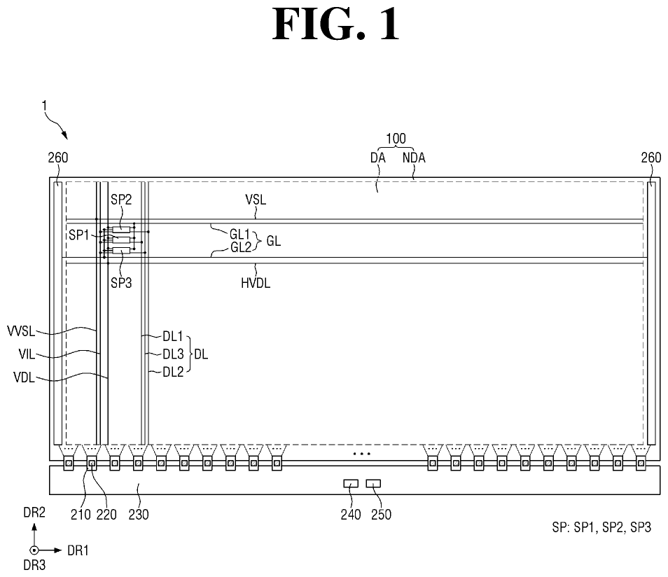

FIG. 1 is a plan view illustrating a display device according to one embodiment.

Referring to FIG. 1, a display device 1, as a device for displaying a moving or still image, may be employed as a display screen of various products such as a television, a laptop computer, a monitor, a billboard, and an Internet of Things (IoT) device as well as portable electronic devices such as a mobile phone, a smartphone, a tablet personal computer (PC), a smart watch, a watch phone, a mobile communication terminal, an electronic notebook, an eBook reader, a portable multimedia player (PMP), a navigation device, and an ultra-mobile PC (UMPC).

The display device 1 may include a display panel 100, a flexible film 210, a display driver 220, a circuit board 230, a timing controller 240, a power supply unit 250, and a gate driver 260.

The display panel 100 may have a rectangular shape in plan view. For example, the display panel 100 may have a rectangular shape, in plan view, having a long side extending in the first direction DR1 and a short side extending in the second direction DR2. A corner where the long side and the short side meet may be right-angled or rounded with a predetermined curvature. The planar shape of the display panel 100 is not limited to the rectangular shape and may be formed in another polygonal shape, a circular shape or an elliptical shape. The display panel 100 may be flat but is not limited thereto. For example, the display panel 100 may be bent with a predetermined curvature.

In the illustrated figure, the first direction DR1 and the second direction DR2 cross each other as horizontal directions and define a horizontal plane. For example, the first direction DR1 and the second direction DR2 may be orthogonal to each other. The third direction DR3 crosses the plane of the first direction DR1 and the second direction DR2, and the first, second, and directions DR3, DR2, and DR1 may be, for example, perpendicular directions orthogonal to each other. In the present specification, directions indicated by arrows of the first to third directions DR1, DR2, and DR3 may be referred to as one side, and the opposite direction may be referred to as the other side.

The display panel 100 may include a display area DA and a non-display area NDA.

The display area DA, which is an area for displaying an image, may be defined as the central area of the display panel 100. FIG. 1 shows the display area DA as including a pixel SP, a gate line GL, a data line DL, an initialization voltage line VIL, a first voltage line VDL, a horizontal voltage line HVDL, a vertical voltage line VVSL, and a second voltage line VSL. The display area DA more generally includes a plurality of each arranged in an array.

The pixels SP may be formed in each pixel area at intersections of the data lines DL and the gate lines GL. The pixels SP may include first to third pixels SP1, SP2, and SP3. In particular, each of the pixels SP may contain a set of three pixels SP1, SP2, and SP3, and the pixels SP1, SP2, and SP3 may be considered to be sub-pixels of the pixel SP that contains them. Each of the first to third pixels SP1, SP2, and SP3 may be connected to the gate line GL and the data line DL. Each of the first to third pixels SP1, SP2, and SP3 may be a minimum unit area that outputs light.

Each of the first to third pixels SP1, SP2, and SP3 may include an organic light emitting diode (OLED) having an organic light emitting layer, a quantum dot light emitting diode (LED) including a quantum dot light emitting layer, a micro LED, or an inorganic LED having an inorganic semiconductor.

The first pixel SP1 may emit light of a first color such as red light, the second pixel SP2 may emit light of a second color such as green light, and the third pixel SP3 may emit light of a third color such as blue light. Pixel circuits of the second pixel SP2, the first pixel SP1, and the third pixel SP3 in a pixel SP may be sequentially arranged in the opposite direction of the second direction DR2, but the arrangement direction of the pixel circuits is not limited thereto.

Each of the gate lines GL may include a first gate line GL1 and a second gate line GL2.

The first gate lines GL1 may extend in the first direction DR1 and may be spaced apart from each other in the second direction DR2. The first gate line GL1 may receive a first gate signal from the gate driver 260 and may supply the first gate signal to the first to third pixels SP1, SP2, and SP3.

The second gate lines GL2 may extend in the first direction DR1 and may be spaced apart from each other in the second direction DR2. The second gate line GL2 may receive a second gate signal from the gate driver 260 and may supply the second gate signal to the first to third pixels SP1, SP2, and SP3.

The data lines DL may extend in the second direction DR2 and may be spaced apart from each other in the first direction DR1. The data lines DL may include first to third data lines DL1, DL2, and DL3. Each of the first to third data lines DL1, DL2, and DL3 may supply a data voltage to each of the first to third pixels SP1, SP2, and SP3.

The initialization voltage lines VIL may extend in the second direction DR2 and may be spaced apart from each other in the first direction DR1. The initialization voltage line VIL may supply the initialization voltage received from the display driver 220 to the pixel circuit of each of the first to third pixels SP1, SP2 and SP3. The initialization voltage line VIL may receive a sensing signal from the pixel circuit of each of the first to third pixels SP1, SP2 and SP3 to supply the sensing signal the display driver 220.

The first voltage lines VDL may extend in the second direction DR2 and may be spaced apart from each other in the first direction DR1. The first voltage line VDL may supply a driving voltage or a high potential voltage received from a power supply unit 250 to the first to third pixels SP1, SP2, and SP3.

The horizontal voltage lines HVDL may extend in the first direction DR1 and may be spaced apart from each other in the second direction DR2. The horizontal voltage line HVDL may be connected to the first voltage line VDL. The horizontal voltage line HVDL may receive a driving voltage or a high potential voltage from the first voltage line VDL.

The vertical voltage lines VVSL may extend in the second direction DR2 and may be spaced apart from each other in the first direction DR1. The vertical voltage line VVSL may be connected to the second voltage line VSL. The vertical voltage line VVSL may supply the low potential voltage received from the power supply unit 250 to the second voltage line VSL.

The second voltage lines VSL may extend in the first direction DR1 and may be spaced apart from each other in the second direction DR2. The second voltage line VSL may supply a low potential voltage to the first to third pixels SP1, SP2, and SP3.

The connection relationship between the pixel SP, the gate line GL, the data line DL, the initialization voltage line VIL, the first voltage line VDL, and the second voltage line VSL may be changed according to the number and arrangement of the pixels SP.

The non-display area NDA may be defined as the remaining area of the display panel 100 outside the display area DA. The non-display area NDA may include, for example, fan-out lines connecting the data line DL, the initialization voltage line VIL, the first voltage line VDL, and the vertical voltage line VVSL to the display driver 220, the gate driver 260, and a pad portion (not shown) connected to the flexible film 210.

The flexible film 210 may be connected to the pad portion and may extend below the non-display area NDA. Input terminals provided on one side of the flexible film 210 may be attached to the circuit board 230 by a film attaching process, and output terminals provided at the other side of the flexible film 210 may be attached to the pad portion by the film attaching process. For example, the flexible film 210 may be bent like a tape carrier package or a chip on film. The flexible film 210 may be bent toward the lower portion of the display panel 100 to reduce the bezel area of the display device 1.

The display driver 220 may be mounted on the flexible film 210. For example, the display driver 220 may be implemented as an integrated circuit (IC). The display driver 220 may receive digital video data and a data control signal from the timing controller 240, and according to the data control signal, the display driver 220 may convert the digital video data to an analog data voltage to supply the analog data voltage to the data lines DL through the fan-out lines.

The circuit board 230 may support the timing controller 240 and the power supply unit 250 and supply signals and power to the display driver 220. For example, the circuit board 230 may supply a signal from the timing controller 240 and a power voltage from the power supply unit 250 to the flexible film 210 and the display driver 220 to emit light from each pixel SP1, SP2, or SP3. To this end, a signal line and a power line may be provided on the circuit board 230.

The timing controller 240 may be mounted on the circuit board 230 and receive image data and a timing synchronization signal from the display driving system or a graphic device through a user connector provided on the circuit board 230. The timing controller 240 may generate digital video data by arranging the image data to fit the pixel arrangement structure based on the timing synchronization signal and may supply the generated digital video data to the display driver 220. The timing controller 240 may generate the data control signal and the gate control signal based on the timing synchronization signal. The timing controller 240 may control the data voltage supply timing of the display driver 220 based on the data control signal and may control the gate signal supply timing of the gate driver 260 based on the gate control signal.

The power supply unit 250 may be disposed on the circuit board 230 to supply a power voltage to the flexible film 210 and the display driver 220. For example, the power supply unit 250 may generate a driving voltage or a high potential voltage and supply it to the first voltage line VDL, may generate a low potential voltage and supply it to the vertical voltage line VVSL, and may generate an initialization voltage and supply it to the initialization voltage line VIL.

The gate driver 260 may be disposed on the left and right sides of the non-display area NDA. The gate driver 260 may generate a gate signal based on the gate control signal supplied from the timing controller 240. The gate control signal may include a start signal, a clock signal, and a power voltage, but the present disclosure is not limited thereto. The gate driver 260 may supply a gate signal to the gate line GL according to a set order.

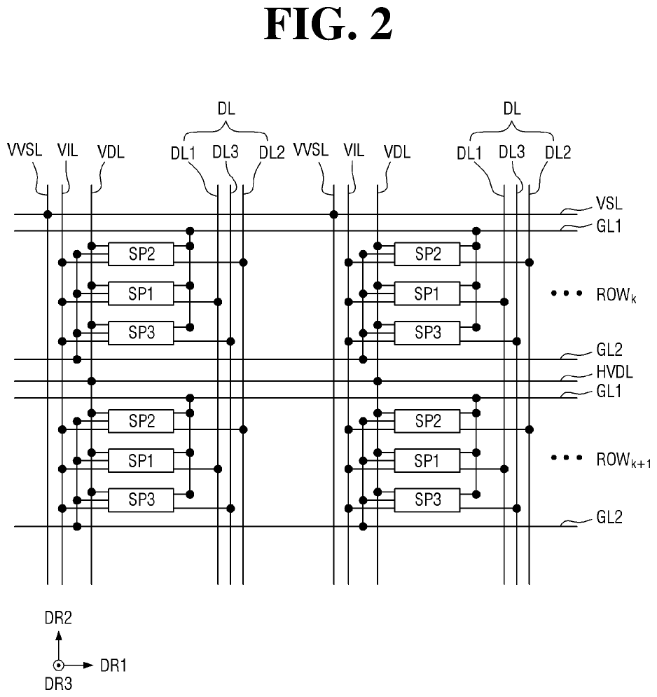

FIG. 2 illustrates an arrangement of pixels and lines in a portion of a display device according to one embodiment.

Referring to FIG. 2, the pixel circuits of the second pixel SP2, the first pixel SP1, and the third pixel SP3 may be sequentially arranged in the opposite direction of the second direction DR2, but the arrangement of the pixel circuits is not limited thereto.

Each of the first to third pixels SP1, SP2, and SP3 may be connected to the first voltage line VDL, the initialization voltage line VIL, the gate line GL, and the data line DL associated with the pixel.

The first voltage line VDL may extend in the second direction DR2. The first voltage line VDL may be disposed to the left of the pixel circuits of the first to third pixels SP1, SP2 and SP3. The first voltage line VDL may supply a driving voltage or high potential voltage to a transistor of each of the first to third pixels SP1, SP2 and SP3.

The horizontal voltage line HVDL may extend in the first direction DR1. The k^{th} horizontal voltage line HVDL may be disposed above the first gate line GL1 disposed in a (k+1)^{th} row ROWₖ₊₁ (k being a positive integer). The horizontal voltage line HVDL may be connected to the first voltage line VDL. The horizontal voltage line HVDL may receive a driving voltage or a high potential voltage from the first voltage line VDL.

The initialization voltage line VIL may extend in the second direction DR2. The initialization voltage line VIL may be disposed to the left of an auxiliary line of the second gate line GL2, the auxiliary line being branched in the second direction DR2 from the second gate line GL2. The initialization voltage line VIL may be disposed between the auxiliary line of the second gate line GL2, which is branched in the second direction DR2, and the vertical voltage line VVSL. The initialization voltage line VIL may supply an initialization voltage to the pixel circuit of each of the first to third pixels SP1, SP2, and SP3. The initialization voltage line VIL may receive a sensing signal from the pixel circuit of each of the first to third pixels SP1, SP2 and SP3 to supply the sensing signal the display driver 220.

The vertical voltage line VVSL may extend in the second direction DR2. The vertical voltage line VVSL may be disposed to the left of the initialization voltage line VIL. The vertical voltage line VVSL may be connected between the power supply unit 250 and the second voltage line VSL. The vertical voltage line VVSL may supply the low potential voltage supplied from the power supply unit 250 to the second voltage line VSL.

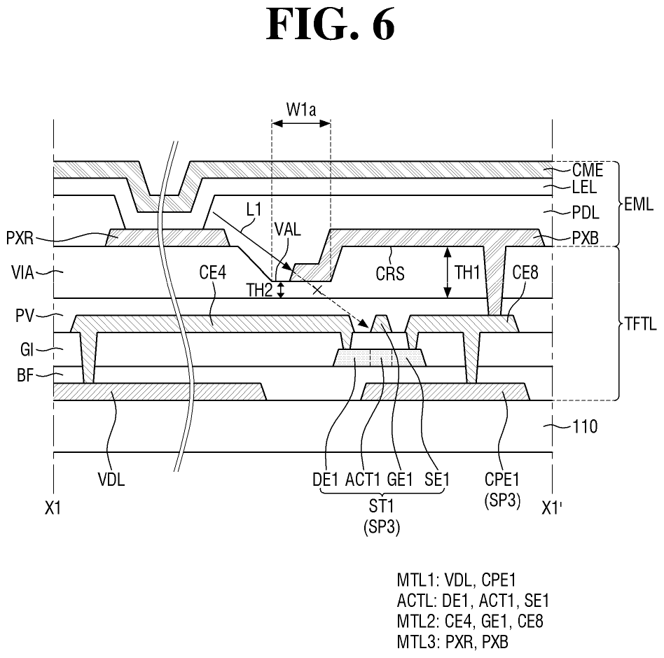

The second voltage line VSL may extend in the first direction DR1. The k^{th} second voltage line VSL may be disposed above the first gate line GL1 disposed in a k^{th} row ROWₖ. The second voltage line VSL may supply the low potential voltage received from the vertical voltage line VVSL to a light emitting element layer EML (see FIG. 6) of the first to third pixels SP1, SP2, and SP3.

The first gate line GL1 may extend in the first direction DR1. The first gate line GL1 may be disposed above the pixel circuit of the first pixel SP1. At least a part of the first gate line GL1 may extend in a direction opposite to the second direction DR2. For example, the first gate line GL1 may include an auxiliary line branching in the direction opposite to the second direction DR2 and extending next to the right sides of the first to third pixels SP1, SP2, and SP3. The auxiliary line of the first gate line GL1 may be disposed to the right of the pixel circuits of the first to third pixels SP1, SP2, and SP3. The first gate line GL1 may supply the first gate signal received from the gate driver 260 to the pixel circuits of the first to third pixels SP1, SP2, and SP3 through the auxiliary line extending in the direction opposite to the second direction DR2.

The second gate line GL2 may extend in the first direction DR1. The second gate line GL2 may be disposed under the pixel circuit of the third pixel SP3. At least a part of the second gate line GL2 may extend in the second direction DR2. For example, the second gate line GL2 may include the auxiliary line branching in the second direction DR2 and extending next to the left side of the first voltage line VDL. The auxiliary line of the second gate line GL2 may be disposed to the left of the first voltage line VDL. The second gate line GL2 may supply the second gate signal received from the gate driver 260 to the pixel circuits of the first to third pixels SP1, SP2, and SP3 through the auxiliary line extending in the second direction DR2.

The data lines DL may extend in the second direction DR2. Each of the data lines DL may supply a data voltage to the pixel SP connected to the data line DL. The data lines DL may include first to third data lines DL1, DL2, and DL3.

The first data line DL1 may extend in the second direction DR2. The first data line DL1 may be disposed to the right of the auxiliary line of the first gate line GL1. The first data line DL1 may supply the data voltage received from the display driver 220 to the pixel circuit of the first pixel SP1.

The third data line DL3 may extend in the second direction DR2. The third data line DL3 may be disposed to the right of the first data line DL1. The third data line DL3 may supply the data voltage received from the display driver 220 to the pixel circuit of the third pixel SP3.

The second data line DL2 may extend in the second direction DR2. The second data line DL2 may be disposed to the right of the third data line DL3. The second data line DL2 may supply the data voltage received from the display driver 220 to the pixel circuit of the second pixel SP2.

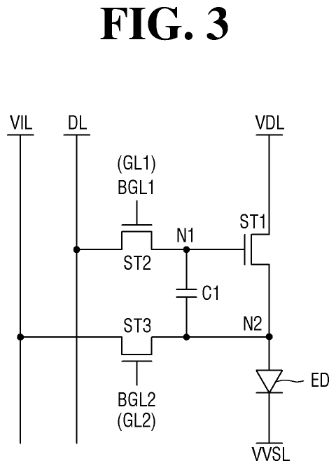

FIG. 3 is an equivalent circuit diagram of a pixel according to one embodiment.

Referring to FIG. 3, the illustrated pixel, which may be any of the first, second, or third pixels SP1, SP2, or SP3 shown in FIG. 2, may be connected to the first voltage line VDL, the data line DL, the initialization voltage line VIL, the first gate line GL1, the second gate line GL2, and the vertical voltage line VVSL that are associated with the pixel. Each of the first to third pixels SP1, SP2, and SP3 may accordingly include a pixel circuit and a light emitting element ED. The pixel circuit of each of the first to third pixels SP1, SP2, and SP3 may include first to third transistors ST1, ST2, and ST3 and a first capacitor C1.

The first transistor ST1 may include a gate electrode, a drain electrode, and a source electrode. The gate electrode of the first transistor ST1 may be connected to a first node N1, the drain electrode of the first transistor ST1 may be connected to the first voltage line VDL, and the source electrode of the first transistors ST1 may be connected to a second node N2. The first transistor ST1 may control a drain-source current (or driving current) based on a data voltage applied to the gate electrode of the first transistor ST1. The first transistor ST1 may be a driving transistor for driving the light emitting element ED.

The light emitting element ED may emit light in response to a driving current. The light emission amount or the luminance that the light emitting element ED produces may be proportional to the magnitude of the driving current. The light emitting element ED may be an organic light emitting diode (OLED) having an organic light emitting layer, a quantum dot light emitting diode (LED) including a quantum dot light emitting layer, a micro LED, or an inorganic LED having an inorganic semiconductor.

The first electrode of the light emitting element ED may be connected to the second node N2, and the second electrode of the light emitting element ED may be connected to the vertical voltage line VVSL. The first electrode of the light emitting element ED may be connected to the source electrode of the first transistor ST1, the drain electrode of the third transistor ST3, and the first capacitor electrode of the first capacitor C1, through the second node N2.

The gate electrode of the second transistor ST2 may be connected to the first gate line GL1, the drain electrode of the second transistor ST2 may be connected to the data line DL, and the source electrode of the second transistor ST2 may be connected to the first node N1. The source electrode of the second transistor ST2 may be connected to the gate electrode of the first transistor ST1 and a second capacitor electrode of the first capacitor C1 through the first node N1. The second transistor ST2 may be turned on or off according to the first gate signal on the first gate line GL1. Accordingly, the first gate signal on the first gate line GL1 may turn on the second transistor ST2 to electrically connect the data line DL to the first node N1, which is or electrically connects to the gate electrode of the first transistor ST1. The second transistor ST2 may be a switching transistor for controlling the current flowing through the first transistor ST1 and the light emitting element ED.

The gate electrode of the third transistor ST3 may be connected to the second gate line GL2, the drain electrode of the third transistors ST3 may be connected to the second node N2, and the source electrode of the third transistor ST3 may be connected to the initialization voltage line VIL. The drain electrode of the third transistor ST3 may be connected to the source electrode of the first transistor ST1, the first capacitor electrode of the first capacitor C1, and the first electrode of the light emitting element ED, through the second node N2. The third transistor ST3 may be turned on or off according to the second gate signal. In particular, the third transistor ST3 may be turned on by the second gate signal of the second gate line GL2 to electrically connect the initialization voltage line VIL to the second node N2, which is or connects to the source electrode of the first transistor ST1. The third transistor ST3 may be turned on according to the second gate signal to supply the sensing signal to the initialization voltage line VIL. The third transistor ST3 may be a switching transistor for controlling the current flowing through the first transistor ST1 and the light emitting element ED.

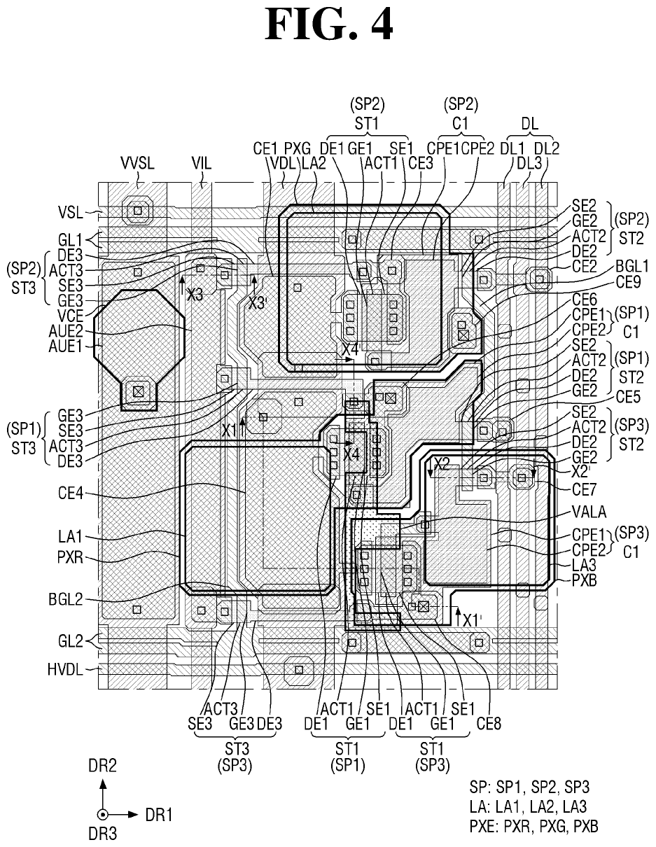

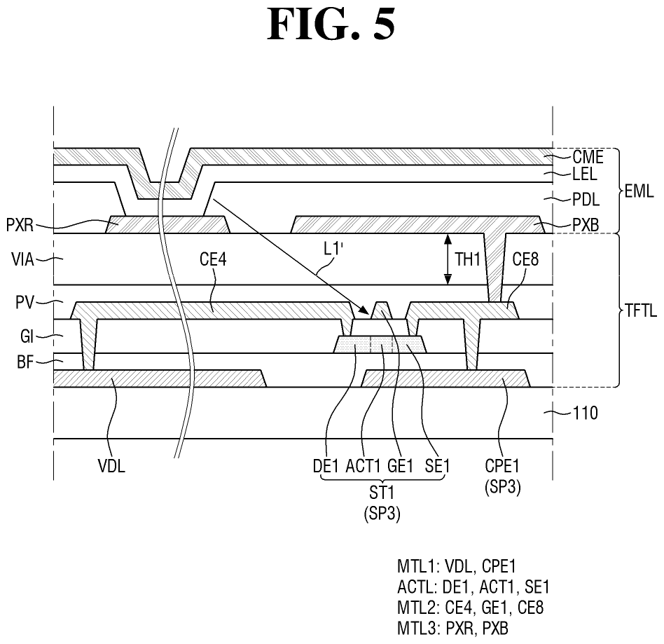

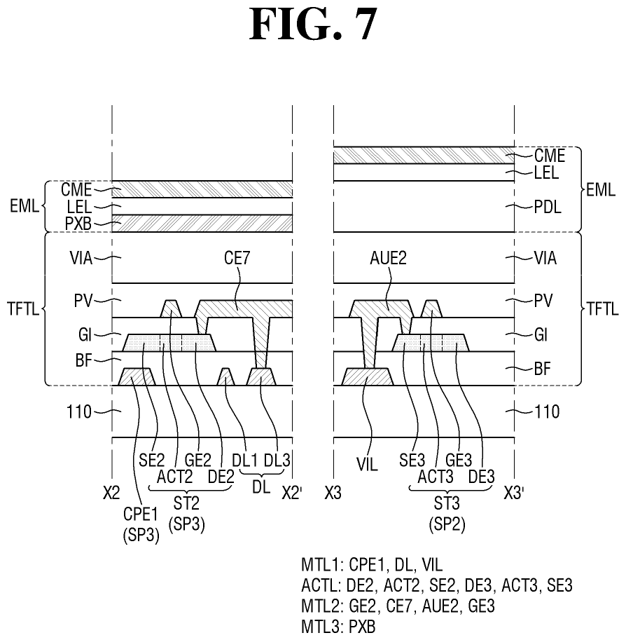

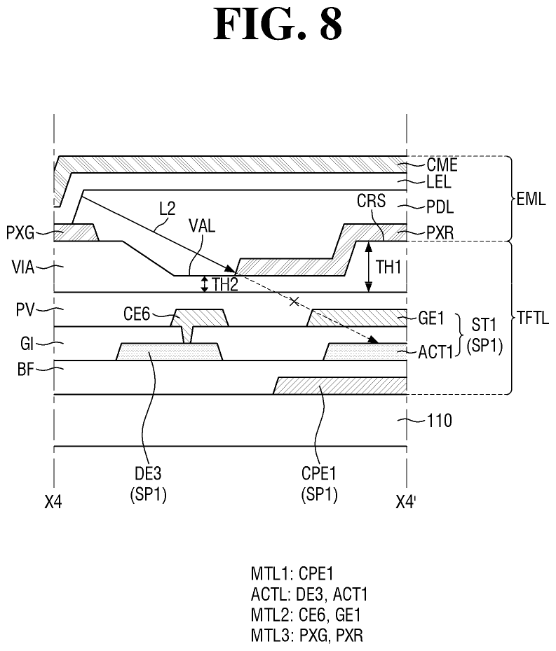

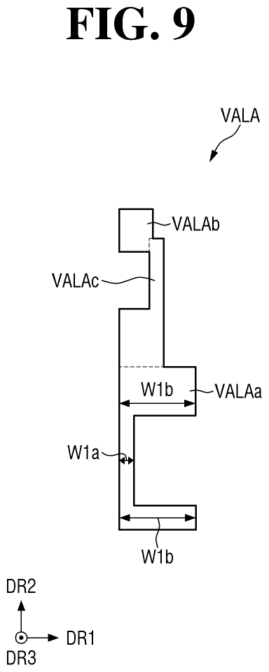

FIG. 4 shows a layout of a portion of a display panel including a pixel SP according to one embodiment. FIG. 5 is a cross-sectional view of a display panel according to a comparative embodiment. FIG. 6 is a cross-sectional view taken along line X1-X1′ of FIG. 4. FIG. 7 is a cross-sectional view taken along lines X2-X2′ and X3-X3′ of FIG. 4. FIG. 8 is a cross-sectional view taken along line X4-X4′ of FIG. 4. FIG. 9 is a plan view of a valley area according to one embodiment. For simplicity of description, a light emitting layer LEL and a common electrode CME are not illustrated in the layout diagram of FIG. 4.

FIG. 4 shows a layout of one pixel SP that includes the first to third pixels SP1, SP2, and SP3. In FIGS. 4 to 9, since the cross sections of the first transistors ST1 of the first to third pixels SP1, SP2, and SP3 are similar to each other, the cross section of the first transistor ST1 of the third pixel SP3 is shown as a representative. In addition, since the cross sections of the second transistors ST2 of the first to third pixels SP1, SP2, and SP3 are similar to each other, the cross section of the second transistor ST2 of the third pixel SP3 is shown as a representative. Since the cross sections of the third transistors ST3 of the first to third pixels SP1, SP2, and SP3 are similar to each other, the cross section of the third transistor ST3 of the second pixel SP2 is shown as a representative.

Referring to FIGS. 4 to 9 in addition to FIG. 3, the display panel may include a substrate 110, a thin film transistor layer TFTL, and the light emitting element layer EML.

The substrate 110 may include a transparent material. For example, the substrate 110 may include a transparent insulating material such as glass, quartz, or the like. The substrate 110 may be a rigid substrate. However, the substrate 110 is not limited thereto, and may include plastic such as polyimide, and may have flexible properties that allow it to be warped, bent, folded, or rolled.

The thin film transistor layer TFTL may be disposed on the substrate 110. The thin film transistor layer TFTL may include a first metal layer MTL1 disposed on the substrate 110, a buffer layer BF covering the first metal layer MTL1, an active layer ACTL disposed on the buffer layer BF, a gate insulating layer GI covering the active layer ACTL, a second metal layer MTL2 disposed on the gate insulating layer GI, a passivation layer PV covering the second metal layer MTL2, and a via layer VIA covering the passivation layer PV.

The first metal layer MTL1 may include the vertical voltage line VVSL, the initialization voltage line VIL, the first voltage line VDL, the data line DL, and a first capacitor electrode CPE1.

The active layer ACTL may include first to third drain electrodes DE1, DE2, and DE3, first to third source electrodes SE1, SE2, and SE3, first to third active regions ACT1, ACT2, and ACT3, and a second capacitor electrode CPE2.

The second metal layer MTL2 may include the horizontal voltage line HVDL, the first gate line GL1, the second gate line GL2, the second voltage line VSL, and first to third gate electrodes GE1, GE2, and GE3, first to ninth connection electrodes CE1, CE2, CE3, CE4, CE5, CE6, CE7, CE8, and CE9, and first and second auxiliary electrodes AUE1 and AUE2.

The buffer layer BF may be disposed on the first metal layer MTL1. The buffer layer BF may be formed of multiple layers in which one or more inorganic layers of a silicon nitride layer, a silicon oxynitride layer, a silicon oxide layer, a titanium oxide layer and an aluminum oxide layer are alternately stacked.

The gate insulating layer GI may be disposed on the active layer ACTL. The gate insulating layer GI may include at least one of silicon oxide (SiOx), silicon nitride (SiNx), or silicon oxynitride (SiOxNy).

The passivation layer PV may be disposed on the second metal layer MTL2. The passivation layer PV may be formed of an inorganic layer, for example, a silicon nitride layer, a silicon oxynitride layer, a silicon oxide layer, a titanium oxide layer, or an aluminum oxide layer. However, the passivation layer PV is not limited thereto, and may be made of an organic insulating material such as polyimide (PI).

The via layer VIA may contain an organic insulating material, e.g., polyimide (PI), and may compensate the stepped portion formed by the conductive layers disposed thereunder to flatten a top surface on which the light emitting element layer EML is formed.

The pixel SP as shown in FIG. 4 may include first to third pixels SP1, SP2, and SP3. The pixel circuits of the second pixel SP2, the first pixel SP1, and the third pixel SP3 may be arranged in the opposite direction of the second direction DR2, but the arrangement of the pixel circuits is not limited thereto.

The first voltage line VDL may extend in the second direction DR2. The first voltage line VDL may be disposed to the left of the pixel circuits of the first to third pixels SP1, SP2 and SP3 in the plan view of FIG. 4. The first voltage line VDL may be disposed in the first metal layer MTL1 on the substrate 110. The first voltage line VDL may overlap a first connection electrode CE1 and a fourth connection electrode CE4 of the second metal layer MTL2.

The first connection electrode CE1 and the fourth connection electrode CE4 may extend in the first direction DR1 and the second direction DR2. The first connection electrode CE1 and the fourth connection electrode CE4 may be disposed in the second metal layer MTL2. The first connection electrode CE1 and the fourth connection electrode CE4 may be connected to the first voltage line VDL through vias. The first voltage line VDL may reduce line resistance by being connected to the first connection electrode CE1 and the fourth connection electrode CE4.

The first connection electrode CE1 may be connected to a first drain electrode DE1 of the first transistor ST1 of the second pixel SP2. Accordingly, the first voltage line VDL may supply a driving voltage to the second pixel SP2 through the first connection electrode CE1.

The fourth connection electrode CE4 may be connected to the first drain electrode DE1 of the first transistor ST1 of each of the first pixel SP1 and the third pixel SP3. Accordingly, the first voltage line VDL may supply a driving voltage to the first pixel SP1 and the third pixel SP3 through the fourth connection electrode CE4.

The first voltage line VDL may be connected to the horizontal voltage line HVDL to supply a driving voltage. The horizontal voltage line HVDL may extend in the first direction DR1. The horizontal voltage line HVDL may be disposed above the first gate line GL1 or below the second gate line GL2 in plan view. The horizontal voltage line HVDL may be disposed in the second metal layer MTL2. The horizontal voltage line HVDL may be connected to the first voltage line VDL to receive the driving voltage.

The initialization voltage line VIL may extend in the second direction DR2. The initialization voltage line VIL may be disposed to the left of the first voltage line VDL in plan view. The initialization voltage line VIL may be disposed in the first metal layer MTL1. The initialization voltage line VIL may overlap a second auxiliary electrode AUE2 of the second metal layer MTL2 and may be electrically connected to the second auxiliary electrode AUE2. The initialization voltage line VIL may reduce line resistance by being connected to the second auxiliary electrode AUE2.

The second auxiliary electrode AUE2 may extend in the second direction DR2. The second auxiliary electrode AUE2 may be disposed in the second metal layer MTL2. The second auxiliary electrode AUE2 may be connected to the third source electrode SE3 of the third transistor ST3 of each of the first to third pixels SP1, SP2, and SP3. Accordingly, the initialization voltage line VIL may supply an initialization voltage to the third transistor ST3 of each of the first to third pixels SP1, SP2, and SP3 through the second auxiliary electrode AUE2 and may receive a sensing signal from the third transistor ST3.

The vertical voltage line VVSL may extend in the second direction DR2. The vertical voltage line VVSL may be disposed to the left of the initialization voltage line VIL in plan view. The vertical voltage line VVSL may be disposed in the first metal layer MTL1. The vertical voltage line VVSL may overlap the first auxiliary electrode AUE1 of the second metal layer MTL2.

The first auxiliary electrode AUE1 may extend in the second direction DR2. The first auxiliary electrode AUE1 may be disposed in the second metal layer MTL2. The first auxiliary electrode AUE1 may be connected to the vertical voltage line VVSL. The vertical voltage line VVSL may reduce line resistance by being connected to the first auxiliary electrode AUE1.

The first auxiliary electrode AUE1 may be connected to a common electrode auxiliary electrode VCE. Accordingly, the vertical voltage line VVSL may supply a low potential voltage to the common electrode CME through the first auxiliary electrode AUE1 and the common electrode auxiliary electrode VCE.

The vertical voltage line VVSL may be connected to the second voltage line VSL to supply a low potential voltage to the second voltage line VSL. The second voltage line VSL may extend in the first direction DR1. The second voltage line VSL may be disposed above the first gate line GL1 or below the second gate line GL2 in plan view. The second voltage line VSL may be disposed in a third metal layer MTL3. The second voltage line VSL may receive a low potential voltage from the vertical voltage line VVSL.

The first gate line GL1 may be disposed above the pixel circuit of the second pixel SP2 in plan view. The first gate line GL1 may be disposed in the second metal layer MTL2. The first gate line GL1 may include a first auxiliary gate line BGL1 that branches and extends in the opposite direction of the second direction DR2 along the right sides of the first to third pixels SP1, SP2, and SP3.

The first auxiliary gate line BGL1 may protrude from the first gate line GL1 in the opposite direction of the second direction DR2 in plan view. The first auxiliary gate line BGL1 may be disposed to the right of the pixel circuits of the first to third pixels SP1, SP2, and SP3 in plan view. That is, the first auxiliary gate line BGL1 may be disposed between the first to third pixels SP1, SP2, and SP3 and the data line DL in plan view. The first gate line GL1 may supply the first gate signal to the second transistor ST2 of each of the first to third pixels SP1, SP2, and SP3 through the first auxiliary gate line BGL1.

The second gate line GL2 may be disposed below the pixel circuits of the first pixel SP1 and the third pixel SP3 in plan view. The second gate line GL2 may be disposed in the second metal layer MTL2. The second gate line GL2 may include a second auxiliary gate line BGL2 branches and extends in the second direction along the left side of the first voltage line VDL.

The second auxiliary gate line BGL2 may protrude from the second gate line GL2 in the second direction DR2 in plan view. The second auxiliary gate line BGL2 may be disposed to the left of the first voltage line VDL in plan view. That is, the second auxiliary gate line BGL2 may be disposed between the initialization voltage line VIL and the first voltage line VDL in plan view. The second gate line GL2 may supply the second gate signal to the third transistor ST3 of each of the first to third pixels SP1, SP2, and SP3 through the second auxiliary gate line BGL2.

The data lines DL may include first to third data lines DL1, DL2, and DL3. Each of the first to third data lines DL1, DL2, and DL3 may extend in the second direction DR2.

The first data line DL1 may be disposed to the right of the first auxiliary gate line BGL1 in plan view. The first data line DL1 may be disposed in the first metal layer MTL1. The fifth connection electrode CE5 of the second metal layer MTL2 may electrically connect the first data line DL1 to the second drain electrode DE2 of the second transistor ST2 of the first pixel SP1. Accordingly, the first data line DL1 may supply a data voltage to the second transistor ST2 of the first pixel SP1 through the fifth connection electrode CE5.

The third data line DL3 may be disposed to the right of the second data line DL2 in plan view. The third data line DL3 may be disposed in the first metal layer MTL1. A seventh connection electrode CE7 of the second metal layer MTL2 may electrically connect the third data line DL3 to the second drain electrode DE2 of the second transistor ST2 of the third pixel SP3. Accordingly, the third data line DL3 may supply a data voltage to the second transistor ST2 of the third pixel SP3 through the seventh connection electrode CE7.

The second data line DL2 may be disposed to the right of the third data line DL3 in plan view. The second data line DL2 may be disposed in the first metal layer MTL1. A second connection electrode CE2 of the second metal layer MTL2 may electrically connect the second data line DL2 to a second drain electrode DE2 of the second transistor ST2 of the second pixel SP2. Accordingly, the second data line DL2 may supply a data voltage to the second transistor ST2 of the second pixel SP2 through the second connection electrode CE2.

The pixel circuit of the first pixel SP1 may include first to third transistors ST1, ST2 and ST3 and a first capacitor C1.

The first transistor ST1 of the first pixel SP1 may include the first active region ACT1, the first gate electrode GE1, the first drain electrode DE1, and the first source electrode SE1.

The first active region ACT1 of the first transistor ST1 may be disposed in the active layer ACTL and may overlap the first gate electrode GE1 of the first transistor ST1.

The first gate electrode GE1 of the first transistor ST1 may be disposed in the second metal layer MTL2. The first gate electrode GE1 of the first transistor ST1 may be connected to the second capacitor electrode CPE2 of the first capacitor C1 of the first pixel SP1. The first gate electrode GE1 of the first transistor ST1 may be electrically connected to the second source electrode SE2 of the second transistor ST2 of the first pixel SP1 through the second capacitor electrode CPE2 of the first capacitor C1.

The first drain electrode DE1 and the first source electrode SE1 of the first transistor ST1 may be made conductive by heat treatment of the active layer ACTL. The first drain electrode DE1 and the first source electrode SE1 of the first transistor ST1 may be made conductive as an N-type semiconductor, but the present disclosure is not limited thereto.

The first drain electrode DE1 of the first transistor ST1 of the first pixel SP1 may be electrically connected to the first voltage line VDL through the fourth connection electrode CE4. The fourth connection electrode CE4 may be connected to the first voltage line VDL1. Accordingly, the first drain electrode DE1 of the first transistor ST1 may receive the driving voltage from the first voltage line VDL through the fourth connection electrode CE4.

The first source electrode SE1 of the first transistor ST1 may be electrically connected to the third drain electrode DE3 of the third transistor ST3, the first capacitor electrode CPE1 of the first capacitor C1, and the light emitting element ED of the first pixel SP1 through the sixth connection electrode CE6.

The first source electrode SE1 of the first transistor ST1 may be electrically connected to the light emitting element ED of the first pixel SP1 through the sixth connection electrode CE6. For example, the first source electrode SE1 of the first transistor ST1 may be electrically connected to a first pixel electrode PXR through the sixth connection electrode CE6. Accordingly, the first source electrode SE1 of the first transistor ST1 may supply a driving current to the light emitting element ED through the first pixel electrode PXR.

The second transistor ST2 of the first pixel SP1 may include a second active region ACT2, a second gate electrode GE2, a second drain electrode DE2, and a second source electrode SE2.

The second active region ACT2 of the second transistor ST2 may be disposed in the active layer ACTL and may overlap the second gate electrode GE2 of the second transistor ST2.

The second gate electrode GE2 of the second transistor ST2 may be disposed in the second metal layer MTL2. The second gate electrode GE2 of the second transistor ST2 may be a part of the first auxiliary gate line BGL1.

The second drain electrode DE2 and the second source electrode SE2 of the second transistor ST2 may be made conductive by heat treatment of the active layer ACTL. The second drain electrode DE2 and the second source electrode SE2 of the second transistor ST2 may be made conductive as an N-type semiconductor, but the present disclosure is not limited thereto.

The second drain electrode DE2 of the second transistor ST2 may be connected to the fifth connection electrode CE5 of the second metal layer MTL2. The second drain electrode DE2 of the second transistor ST2 may be electrically connected to the first data line DL1 through the fifth connection electrode CE5 of the second metal layer MTL2. Accordingly, the first data line DL1 may supply a data voltage to the second transistor ST2 of the first pixel SP1 through the fifth connection electrode CE5.

The second source electrode SE2 of the second transistor ST2 may be electrically connected to the second capacitor electrode CPE2 of the first capacitor C1 of the first pixel SP1. The second capacitor electrode CPE2 may be connected to the first gate electrode GE1 of the first transistor ST1. Accordingly, the second source electrode SE2 of the second transistor ST2 may supply a first gate voltage to the first transistor ST1 through the second capacitor electrode CPE2.

The third transistor ST3 of the first pixel SP1 may include a third active region ACT3, a third gate electrode GE3, a third drain electrode DE3, and a third source electrode SE3.

The third active region ACT3 of the third transistor ST3 may be disposed in the active layer ACTL and may overlap the third gate electrode GE3 of the third transistor ST3.

The third gate electrode GE3 of the third transistor ST3 may be disposed in the second metal layer MTL2. The third gate electrode GE3 of the third transistor ST3 may be a part of the second auxiliary gate line BGL2.

The third drain electrode DE3 and the third source electrode SE3 of the third transistor ST3 may be made conductive by heat treatment of the active layer ACTL. The third drain electrode DE3 and the third source electrode SE3 of the third transistor ST3 may be made conductive as an N-type semiconductor, but the present disclosure is not limited thereto.

The third drain electrode DE3 of the third transistor ST3 may be connected to the sixth connection electrode CE6 of the second metal layer MTL2. The third drain electrode DE3 of the third transistor ST3 may be electrically connected to the first source electrode SE1 of the first transistor ST1, the first capacitor electrode CPE1 of the first capacitor C1, and the first pixel electrode PXR of the first pixel SP1 through the sixth connection electrode CE6.

The third source electrode SE3 of the third transistor ST3 may be connected to the second auxiliary electrode AUE2 of the second metal layer MTL2. The third source electrode SE3 of the third transistor ST3 may be electrically connected to the initialization voltage line VIL through the second auxiliary electrode AUE2. The third source electrode SE3 of the third transistor ST3 may receive the initialization voltage from the initialization voltage line VIL. The third source electrode SE3 of the third transistor ST3 may supply the sensing signal to the initialization voltage line VIL.

The first capacitor C1 of the first pixel SP1 may include the first capacitor electrode CPE1 disposed in the first metal layer MTL1 and the second capacitor electrode CPE2 disposed in the active layer ACTL. The first capacitor electrode CPE1 may be connected to the first source electrode SE1 of the first transistor ST1, the third drain electrode DE3 of the third transistor ST3, and the first pixel electrode PXR of the first pixel SP1 through the sixth connection electrode CE6. The second capacitor electrode CPE2 may be connected to the first gate electrode GE1 of the first transistor ST1 and the second source electrode SE2 of the second transistor ST2.

The pixel circuit of the second pixel SP2 may include first to third transistors ST1, ST2, and ST3 and a first capacitor C1.

The first transistor ST1 of the second pixel SP2 may include a first active region ACT1, a first gate electrode GE1, a first drain electrode DE1, and a first source electrode SE1 of the second pixel SP2.

The first active region ACT1 of the first transistor ST1 may be disposed in the active layer ACTL and may overlap the first gate electrode GE1 of the first transistor ST1.

The first gate electrode GE1 of the first transistor ST1 may be disposed in the second metal layer MTL2. The first gate electrode GE1 of the first transistor ST1 may be connected to the second capacitor electrode CPE2 of the first capacitor C1 of the second pixel SP2. The first gate electrode GE1 of the first transistor ST1 may be electrically connected to the second source electrode SE2 of the second transistor ST2 through the second capacitor electrode CPE2 of the first capacitor C1.

The first drain electrode DE1 and the first source electrode SE1 of the first transistor ST1 may be made conductive by heat treatment of the active layer ACTL. The first drain electrode DE1 and the first source electrode SE1 of the first transistor ST1 may be made conductive as an N-type semiconductor, but the present disclosure is not limited thereto.

The first drain electrode DE1 of the first transistor ST1 may be electrically connected to the first voltage line VDL through the first connection electrode CE1. The first connection electrode CE1 may be connected to the first voltage line VDL. Accordingly, the first drain electrode DE1 of the first transistor ST1 may receive the driving voltage from the first voltage line VDL through the first connection electrode CE1.

The first source electrode SE1 of the first transistor ST1 may be electrically connected to the third drain electrode DE3 of the third transistor ST3 and the first capacitor electrode CPE1 of the first capacitor C1 through the third connection electrode CE3.

The first source electrode SE1 of the first transistor ST1 may be electrically connected to the light emitting element ED of the second pixel SP2 through the third connection electrode CE3, the first capacitor electrode CPE1 of the first capacitor C1, and the ninth connection electrode CE9. For example, the first source electrode SE1 of the first transistor ST1 may be electrically connected to a second pixel electrode PXG through the third connection electrode CE3, the first capacitor electrode CPE1 of the first capacitor C1, and the ninth connection electrode CE9. Accordingly, the first source electrode SE1 of the first transistor ST1 may supply a driving current to the light emitting element ED through the second pixel electrode PXG.

The second transistor ST2 of the second pixel SP2 may include a second active region ACT2, a second gate electrode GE2, a second drain electrode DE2, and a second source electrode SE2.

The second active region ACT2 of the second transistor ST2 may be disposed in the active layer ACTL and may overlap the second gate electrode GE2 of the second transistor ST2.

The second gate electrode GE2 of the second transistor ST2 may be disposed in the second metal layer MTL2. The second gate electrode GE2 of the second transistor ST2 may be a part of the first auxiliary gate line BGL1.

The second drain electrode DE2 and the second source electrode SE2 of the second transistor ST2 may be made conductive by heat treatment of the active layer ACTL. The second drain electrode DE2 and the second source electrode SE2 of the second transistor ST2 may be made conductive as an N-type semiconductor, but the present disclosure is not limited thereto.

The second drain electrode DE2 of the second transistor ST2 may be connected to the second connection electrode CE2 of the second metal layer MTL2. The second drain electrode DE2 of the second transistor ST2 may be electrically connected to the second data line DL2 through the second connection electrode CE2 of the second metal layer MTL2. Accordingly, the second data line DL2 may supply a data voltage to the second transistor ST2 of the second pixel SP2 through the second connection electrode CE2.

The second source electrode SE2 of the second transistor ST2 may be electrically connected to the first capacitor C1 and particularly to the second capacitor electrode CPE2 form in the active layer ACTL. The second capacitor electrode CPE2 may be connected to the first gate electrode GE1 of the first transistor ST1. Accordingly, the second source electrode SE2 of the second transistor ST2 may supply a first gate voltage to the first transistor ST1 through the second capacitor electrode CPE2.

The third transistor ST3 of the second pixel SP2 may include a third active region ACT3, a third gate electrode GE3, a third drain electrode DE3, and a third source electrode SE3.

The third active region ACT3 of the third transistor ST3 may be disposed in the active layer ACTL and may overlap the third gate electrode GE3 of the third transistor ST3.

The third gate electrode GE3 of the third transistor ST3 may be disposed in the second metal layer MTL2. The third gate electrode GE3 of the third transistor ST3 may be a part of the second auxiliary gate line BGL2.

The third drain electrode DE3 and the third source electrode SE3 of the third transistor ST3 may be made conductive by heat treatment of the active layer ACTL. The third drain electrode DE3 and the third source electrode SE3 of the third transistor ST3 may be made conductive as an N-type semiconductor, but the present disclosure is not limited thereto.

The third drain electrode DE3 of the third transistor ST3 may be connected to the third connection electrode CE3 of the second metal layer MTL2. The third drain electrode DE3 of the third transistor ST3 may be electrically connected to the first source electrode SE1 of the first transistor ST1 and the first capacitor electrode CPE1 of the first capacitor C1 through the third connection electrode CE3. The third drain electrode DE3 of the third transistor ST3 may be electrically connected to the second pixel electrode PXG through the third connection electrode CE3, the first capacitor electrode CPE1, and the ninth connection electrode CE9.

The third source electrode SE3 of the third transistor ST3 may be connected to the second auxiliary electrode AUE2 of the second metal layer MTL2. The third source electrode SE3 of the third transistor ST3 may be electrically connected to the initialization voltage line VIL through the second auxiliary electrode AUE2. The third source electrode SE3 of the third transistor ST3 may receive the initialization voltage from the initialization voltage line VIL. The third source electrode SE3 of the third transistor ST3 may supply the sensing signal to the initialization voltage line VIL.

The first capacitor C1 of the second pixel SP2 may include the first capacitor electrode CPE1 disposed in the first metal layer MTL1 and the second capacitor electrode CPE2 disposed in the active layer ACTL. The first capacitor electrode CPE1 may be connected to the first source electrode SE1 of the first transistor ST1 and the third drain electrode DE3 of the third transistor ST3 through the third connection electrode CE3. The first capacitor electrode CPE1 may be connected to the second pixel electrode PXG of the second pixel SP2 through the ninth connection electrode CE9. The second capacitor electrode CPE2 may be connected to the first gate electrode GE1 of the first transistor ST1 and the second source electrode SE2 of the second transistor ST2.

The pixel circuit of the third pixel SP3 may include first to third transistors ST1, ST2 and ST3 and a first capacitor C1.

The first transistor ST1 of the third pixel SP3 may include a first active region ACT1, a first gate electrode GE1, a first drain electrode DE1, and a first source electrode SE1.

The first active region ACT1 of the first transistor ST1 may be disposed in the active layer ACTL and may overlap the first gate electrode GE1 of the first transistor ST1.

The first gate electrode GE1 of the first transistor ST1 may be disposed in the second metal layer MTL2. The first gate electrode GE1 of the first transistor ST1 may be connected to the second capacitor electrode CPE2 of the first capacitor C1. The first gate electrode GE1 of the first transistor ST1 may be electrically connected to the second source electrode SE2 of the second transistor ST2 through the second capacitor electrode CPE2 of the first capacitor C1.

The first drain electrode DE1 and the first source electrode SE1 of the first transistor ST1 may be made conductive by heat treatment of the active layer ACTL. The first drain electrode DE1 and the first source electrode SE1 of the first transistor ST1 may be made conductive as an N-type semiconductor, but the present disclosure is not limited thereto.

The first drain electrode DE1 of the first transistor ST1 may be electrically connected to the first voltage line VDL through the fourth connection electrode CE4. The fourth connection electrode CE4 may be connected to the first voltage line VDL. Accordingly, the first drain electrode DE1 of the first transistor ST1 may receive the driving voltage from the first voltage line VDL through the fourth connection electrode CE4.

The first source electrode SE1 of the first transistor ST1 may be electrically connected to the third drain electrode DE3 of the third transistor ST3, the first capacitor electrode CPE1 of the first capacitor C1, and the light emitting element ED of the third pixel SP3 through the eighth connection electrode CE8.

The first source electrode SE1 of the first transistor ST1 may be electrically connected to the light emitting element ED of the third pixel SP3 through the eighth connection electrode CE8. For example, the first source electrode SE1 of the first transistor ST1 may be electrically connected to a third pixel electrode PXB through the eighth connection electrode CE8. Accordingly, the first source electrode SE1 of the first transistor ST1 may supply a driving current to the light emitting element ED through the third pixel electrode PXB.

The second transistor ST2 of the third pixel SP3 may include a second active region ACT2, a second gate electrode GE2, a second drain electrode DE2, and a second source electrode SE2.

The second active region ACT2 of the second transistor ST2 may be disposed in the active layer ACTL and may overlap the second gate electrode GE2 of the second transistor ST2.

The second gate electrode GE2 of the second transistor ST2 may be disposed in the second metal layer MTL2. The second gate electrode GE2 of the second transistor ST2 may be a part of the first auxiliary gate line BGL1.

The second drain electrode DE2 and the second source electrode SE2 of the second transistor ST2 may be made conductive by heat treatment of the active layer ACTL. The second drain electrode DE2 and the second source electrode SE2 of the second transistor ST2 may be made conductive as an N-type semiconductor, but the present disclosure is not limited thereto.

The second drain electrode DE2 of the second transistor ST2 may be connected to the seventh connection electrode CE7 of the second metal layer MTL2. The second drain electrode DE2 of the second transistor ST2 may be electrically connected to the third data line DL3 through the seventh connection electrode CE7 of the second metal layer MTL2. Accordingly, the third data line DL3 may supply a data voltage to the second transistor ST2 of the third pixel SP3 through the seventh connection electrode CE7.

The second source electrode SE2 of the second transistor ST2 may be electrically connected to the first capacitor C1 and particularly to the second capacitor electrode CPE2 formed in the active layer ACTL. The second capacitor electrode CPE2 may be connected to the first gate electrode GE1 of the first transistor ST1. Accordingly, the second source electrode SE2 of the second transistor ST2 may supply a first gate voltage to the first transistor ST1 through the second capacitor electrode CPE2.

The third transistor ST3 of the third pixel SP3 may include a third active region ACT3, a third gate electrode GE3, a third drain electrode DE3, and a third source electrode SE3.

The third active region ACT3 of the third transistor ST3 may be disposed in the active layer ACTL and may overlap the third gate electrode GE3 of the third transistor ST3.

The third gate electrode GE3 of the third transistor ST3 may be disposed in the second metal layer MTL2. The third gate electrode GE3 of the third transistor ST3 may be a part of the second auxiliary gate line BGL2.

The third drain electrode DE3 and the third source electrode SE3 of the third transistor ST3 may be made conductive by heat treatment of the active layer ACTL. The third drain electrode DE3 and the third source electrode SE3 of the third transistor ST3 may be made conductive as an N-type semiconductor, but the present disclosure is not limited thereto.

The third drain electrode DE3 of the third transistor ST3 may be connected to the eighth connection electrode CE8 of the second metal layer MTL2. The third drain electrode DE3 of the third transistor ST3 may be electrically connected to the first source electrode SE1 of the first transistor ST1, the first capacitor electrode CPE1 of the first capacitor C1, and the third pixel electrode PXB of the third pixel SP3 through the eighth connection electrode CE8.

The third source electrode SE3 of the third transistor ST3 may be connected to the second auxiliary electrode AUE2 of the second metal layer MTL2. The third source electrode SE3 of the third transistor ST3 may be electrically connected to the initialization voltage line VIL through the second auxiliary electrode AUE2. The third source electrode SE3 of the third transistor ST3 may receive the initialization voltage from the initialization voltage line VIL. The third source electrode SE3 of the third transistor ST3 may supply the sensing signal to the initialization voltage line VIL.

The first capacitor C1 of the third pixel SP3 may include the first capacitor electrode CPE1 disposed in the first metal layer MTL1 and the second capacitor electrode CPE2 disposed in the active layer ACTL. The first capacitor electrode CPE1 may be connected to the first source electrode SE1 of the first transistor ST1, the third drain electrode DE3 of the third transistor ST3, and the third pixel electrode PXB of the third pixel SP3 through the eighth connection electrode CE8. The second capacitor electrode CPE2 may be connected to the first gate electrode GE1 of the first transistor ST1 and the second source electrode SE2 of the second transistor ST2.

The light emitting element layer EML may be disposed on the thin film transistor layer TFTL as shown in FIGS. 5 to 8. The light emitting element layer EML may include the third metal layer MTL3 disposed on the via layer VIA, a pixel defining layer PDL disposed on the third metal layer MTL3 and the via layer VIA, the light emitting layer LEL disposed on the third metal layer MTL3 and the pixel defining layer PDL, and the common electrode CME disposed on the light emitting layer LEL.

The third metal layer MTL3 may be disposed on the via layer VIA. The third metal layer MTL3 may include a pixel electrode PXE and the common electrode auxiliary electrode VCE. The pixel electrode PXE may include a first electrode (e.g., an anode electrode) of a light emitting diode. The pixel electrode PXE may include the first pixel electrode PXR of the first pixel SP1, the second pixel electrode PXG of the second pixel SP2, and the third pixel electrode PXB of the third pixel SP3.

The first pixel electrode PXR of the first pixel SP1 may be disposed substantially at the center and lower left end of the pixel SP. For example, the first pixel electrode PXR may overlap the initialization voltage line VIL, the first voltage line VDL, and the pixel circuit of the first pixel SP1 in the third direction DR3. The first pixel electrode PXR may extend in a diagonal direction between the first direction DR1 and the second direction DR2.

The first pixel electrode PXR may be electrically connected to the first source electrode SE1 of the first transistor ST1 of the first pixel SP1 through the sixth connection electrode CE6 and a contact hole overlapping the sixth connection electrode CE6. The first pixel electrode PXR may receive the driving voltage from the first voltage line VDL through the first source electrode SE1 of the first transistor ST1 of the first pixel SP1.

The second pixel electrode PXG of the second pixel SP2 may be disposed substantially at the center and upper end of the pixel SP in plan view. For example, the second pixel electrode PXG may overlap the first voltage line VDL, the pixel circuit of the second pixel SP2, the first gate line GL1, and the second voltage line VSL in the third direction DR3.

The second pixel electrode PXG may be connected to the first source electrode SE1 of the first transistor ST1 of the second pixel SP2 through the ninth connection electrode CE9, a contact hole overlapping the ninth connection electrode CE9, the first capacitor electrode CPE1, and the third connection electrode CE3. The second pixel electrode PXG may receive the driving voltage from the first voltage line VDL through the first source electrode SE1 of the first transistor ST1 of the second pixel SP2.

The third pixel electrode PXB of the third pixel SP3 may be disposed substantially at the center and lower right end of the pixel SP in plan view. For example, the third pixel electrode PXB may overlap the data line DL and the pixel circuit of the third pixel SP3 in the third direction DR3.

The third pixel electrode PXB may be connected to the first source electrode SE1 of the first transistor ST1 of the third pixel SP3 through the eighth connection electrode CE8 and a contact hole overlapping the eighth connection electrode CE8. The third pixel electrode PXB may receive the driving voltage from the first voltage line VDL through the first source electrode SE1 of the first transistor ST1 of the third pixel SP3.

The common electrode auxiliary electrode VCE may be disposed substantially at the left side of the pixel SP in plan view. The common electrode auxiliary electrode VCE may overlap the vertical voltage line VVSL in the third direction DR3.

The common electrode auxiliary electrode VCE may be connected to the first auxiliary electrode AUE1 through a contact hole. The common electrode auxiliary electrode VCE may receive a low potential voltage from the vertical voltage line VVSL through the first auxiliary electrode AUE1.

The pixel defining layer PDL as shown in FIGS. 5 to 8 may be disposed on the via layer VIA of the thin film transistor layer TFTL and the third metal layer MTL3. The pixel defining layer PDL may electrically insulate the patterned third metal layer MTL3. The pixel defining layer PDL may include a plurality of open portions. Some of the plurality of open portions may expose a part of the third metal layer MTL3. The pixel electrode PXE of the third metal layer MTL3 may be in contact with the light emitting layer LEL through the plurality of open portions.

An emission area LA may be defined by the open portion of the pixel defining layer PDL. For example, a first emission area LA1 may be defined by the open portion of the pixel defining layer PDL overlapping the first pixel electrode PXR, a second emission area LA2 may be defined by the open portion of the pixel defining layer PDL overlapping the second pixel electrode PXG, and a third emission area LA3 may be defined by the open portion of the pixel defining layer PDL overlapping the third pixel electrode PXB. The first to third emission areas LA1, LA2, and LA3 may have sizes smaller than those of the first to third pixel electrodes PXR, PXG, and PXB, respectively.

The first emission area LA1 may be disposed substantially at the lower left end of the pixel SP in plan view. The first emission area LA1 may overlap most of the first pixel electrode PXR. The second emission area LA2 may be disposed substantially at the upper center of the pixel SP in plan view. The second emission area LA2 may overlap most of the second pixel electrode PXG. The third emission area LA3 may be disposed substantially at the lower right end of the pixel SP in plan view. The third emission area LA3 may overlap most of the third pixel electrode PXB.

Each of contact holes through which each of the first to third pixel electrodes PXR, PXG, and PXB is electrically connected to the first source electrode SE1 of the first transistor ST1 of the associated pixel SP1, SP2, or SP3 may not overlap the open portion of the pixel defining layer PDL.

The light emitting layer LEL may be disposed on the third metal layer MTL3 and the pixel defining layer PDL. In one embodiment, the light emitting layer LEL may be integrally disposed across the entire surface of the display area. The light emitting layer LEL may be physically connected across the emission area LA and the pixel SP. The light emitting layer LEL may be disposed across the emission area LA and the pixel SP. For example, the light emitting layer LEL may be in direct contact with the pixel electrode PXE exposed by the pixel defining layer PDL and may also be in direct contact with the side and top surfaces of the pixel defining layer PDL. Accordingly, the wavelength of light emitted from the light emitting layer LEL may be the same for each of the emission areas LA1, LA2, and LA3. For example, the light emitting layer LEL of each of the emission areas LA1, LA2, and LA3 may emit blue light or ultraviolet light. In this case, a color control structure disposed above the light emitting element layer EML may include a wavelength conversion layer to display a color for each pixel SP1, SP2, or SP3.

In another embodiment, the light emitting layer LEL may include regions of different material spaced apart from each other respectively for the emission areas LA1, LA2, and LA3 distinguished by the pixel defining layer PDL. In this case, the wavelength of light emitted from each region of light emitting layer LEL may be different for each of the emission areas LA1, LA2, and LA3.

The common electrode CME may be arranged on the light emitting layer LEL. The common electrode CME may be integrally disposed across the entire surface of the display area. The common electrode CME may be physically connected across the emission area LA and the pixel SP. The common electrode CME may be disposed across the emission area LA and the pixel SP. The common electrode CME may be a second electrode (e.g., a cathode electrode) of a light emitting diode.

The pixel electrode PXE, the light emitting layer LEL, and the common electrode CME may constitute a light emitting element (e.g., an OLED). Light emitted from the light emitting layer LEL may be emitted upward through the common electrode CME.

In some embodiments, part of light emitted from the light emitting layer LEL may be emitted toward the thin film transistor layer TFTL. When the light emitted from the light emitting layer LEL is incident on the active layer ACTL of the first transistor ST1 serving as a driving transistor, the quality of the display device 1 may deteriorate due to light induced degradation. The light induced degradation refers to a phenomenon in which an inherent characteristic curve between a drain-source current Ids and a gate voltage Vg of a transistor is shifted due to external light incident on the transistor, resulting in a change in the magnitude of a threshold voltage Vth.

As shown in FIGS. 5 and 6, in the display device 1 according to the comparative embodiment and an exemplary embodiment, no other metal layer may be disposed between the second metal layer MTL2 where the gate electrode of the transistor is disposed and the third metal layer MTL3 where the pixel electrode PXE is disposed. This arrangement, which minimizes the number of stacks, may improve process efficiency.

However, as the height difference between the active layer ACTL and the third metal layer MTL3 decreases, as in the comparative embodiment shown in FIG. 5, among light emitted from the light emitting layer LEL disposed on the first pixel electrode PXR of the first pixel SP1, some light L1′ may be incident on the active layer ACTL of the first transistor ST1 of the third pixel SP3. As a result, light induced degradation may occur in the first transistor ST1 of the third pixel SP3 due to the light L1′ emitted from the first pixel SP1.

On the other hand, in the display device 1 according to the embodiment of FIG. 6, the via layer VIA may include a valley VAL to place a part of the pixel electrode PXE extending into the valley VAL at a lower height, thereby blocking a light path and preventing light emitted from the light emitting layer LEL disposed on the pixel electrode PXE of an adjacent pixel from being incident on a transistor within its own pixel. Therefore, light induced degradation of the transistor may be reduced or minimized.

For example, as shown in FIG. 6, the via layer VIA may include a crest CRS and the valley VAL. The crest CRS may be a portion of the via layer VIA where the thickness of the via layer VIA is the greatest, and the valley VAL may be a portion of the via layer VIA where the thickness of the via layer VIA is the smallest. The via layer VIA may include an area where the valley VAL is positioned, that is, a valley area VALA. A slope may be disposed between the crest CRS and the valley VAL.

A thickness TH2 of the valley VAL may be smaller than a thickness TH1 of the crest CRS. For example, the thickness TH1 of the crest CRS may be 3 to 5 times the thickness TH2 of the valley VAL. The thicknesses TH1 and TH2 of the crest CRS and the valley VAL may mean a vertical distance from the top surface of the passivation layer PV to the top surface of the via layer VIA.

Most of the area of the pixel electrode PXE may be disposed on the crest CRS of the via layer VIA. For example, as shown in FIG. 4, the second pixel electrode PXG may not overlap the valley area VALA. A part of the first pixel electrode PXR and a part of the third pixel electrode PXB may overlap the valley area VALA.

By placing most of the area of the pixel electrode PXE on the crest CRS of the via layer VIA, the capacitance of the first capacitors C1 of the first to third pixels SP1, SP2, and SP3 may be sufficiently secured. For example, the first capacitor C1 of each of the first to third pixels SP1, SP2, and SP3 may overlap the crest CRS in the third direction DR3. Since the first capacitor electrodes CPE1 of the first capacitors C1 may be connected to the pixel electrode PXE through the connection electrodes CE6, CE8, and CE9, the via layer VIA overlapping the first capacitors C1 may be formed as the crest CRS to ensure sufficient capacitance.

Meanwhile, portions where the first pixel electrode PXR and the third pixel electrode PXB overlap the valley area VALA may not overlap the first emission area LA1 and the third emission area LA3, respectively. That is, the valley area VALA may not overlap the first to third emission areas LA1, LA2, and LA3. Therefore, a color difference phenomenon between adjacent pixels SP may be minimized. The color difference phenomenon means that incorrect light emission occurs due to a coupling phenomenon with the pixel circuit of an adjacent pixel.

One end of the third pixel electrode PXB facing the first pixel electrode PXR may be disposed on the valley VAL of the via layer VIA. That is, one end of the third pixel electrode PXB facing the first pixel electrode PXR may be disposed in the valley area VALA. Accordingly, since one end of the third pixel electrode PXB extends to a lower height than the first pixel electrode PXR, light L1 emitted at a downward angle from the light emitting layer LEL disposed on the first pixel electrode PXR may be prevented from being incident on the active layer ACTL of the first transistor ST1 of the third pixel SP3. Therefore, light induced degradation of the first transistor ST1 may be reduced or minimized.

Similarly, as shown in FIG. 8, one end of the first pixel electrode PXR facing the second pixel electrode PXG may be disposed on the valley VAL of the via layer VIA. That is, one end of the first pixel electrode PXR facing the second pixel electrode PXG may extend into and be disposed in the valley area VALA. Accordingly, since one end of the first pixel electrode PXR is placed at a lower height than the second pixel electrode PXG, light L2 emitted downward from the light emitting layer LEL disposed on the second pixel electrode PXG may be prevented from being incident on the active layer ACTL of the first transistor ST1 of the first pixel SP1. Therefore, light induced degradation of the first transistor ST1 may be reduced or minimized.

As shown in FIGS. 4 and 9, the valley area VALA may include a first region VALAa, a second region VALAb, and a third region VALAc.

The first region VALAa may be disposed between the first pixel electrode PXR and the third pixel electrode PXB. For example, the first region VALAa may be disposed between the first pixel electrode PXR and the first transistor ST1 of the third pixel SP3 in plan view. The first region VALAa may overlap the end of the third pixel electrode PXB facing the first pixel electrode PXR in the third direction DR3.

The first region VALAa may be disposed to surround at least a part of the first transistor ST1 of the third pixel SP3 in plan view. The first region VALAa may be disposed to surround a side of the first transistor ST1 of the third pixel SP3 facing the first pixel electrode PXR in plan view.

A width W1a in the first direction DR1 of a part of the first region VALAa extending along the second direction DR2 may be smaller than a width W1b in the first direction DR1 of a part of the first region VALAa extending along the first direction DR1. The width W1b in the first direction DR1 of a part of the first region VALAa extending along the first direction DR1 may be 3 to 5 times the width W1a in the first direction DR1 of a part of the first region VALAa extending along the second direction DR2.

The second region VALAb may be disposed between the first pixel electrode PXR and the second pixel electrode PXG. For example, the second region VALAb may be disposed between the second pixel electrode PXG and the first transistor ST1 of the first pixel SP1 in plan view. The second region VALAb may be disposed between the second pixel electrode PXG and a side of the first transistor ST1 of the first pixel SP1 facing the second pixel electrode PXG in plan view. The second region VALAb may overlap the end of the first pixel electrode PXR facing the second pixel electrode PXG in the third direction DR3.

The third region VALAc may connect the first region VALAa to the second region VALAb. The third region VALAc may be disposed between the first pixel electrode PXR and the third pixel electrode PXB. For example, the third region VALAc may be disposed between the third pixel electrode PXB and the first transistor ST1 of the first pixel SP1. The third region VALAc may overlap the end of the first pixel electrode PXR facing the third pixel electrode PXB in the third direction DR3.

The third region VALAc may be disposed to surround at least a part of the first transistor ST1 of the first pixel SP1 in plan view. The third region VALAc may be disposed to surround a side of the first transistor ST1 of the first pixel SP1 facing the third pixel electrode PXB in plan view.

Hereinafter, some other embodiments of the display device will be described. In the following, description of components that are the same as components of the above-described embodiment, which are denoted by like reference numerals, will be omitted or simplified, and differences in the embodiments will be mainly described.

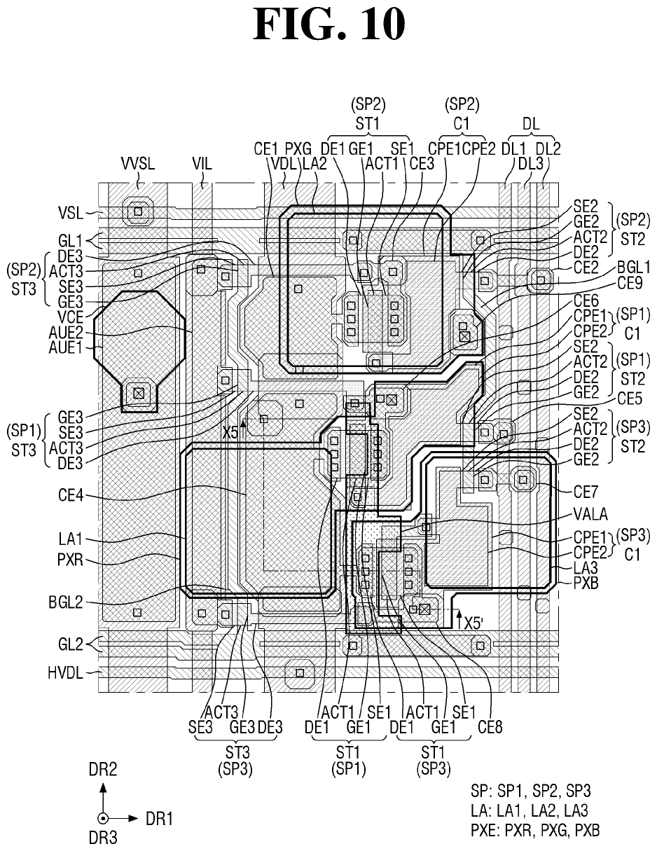

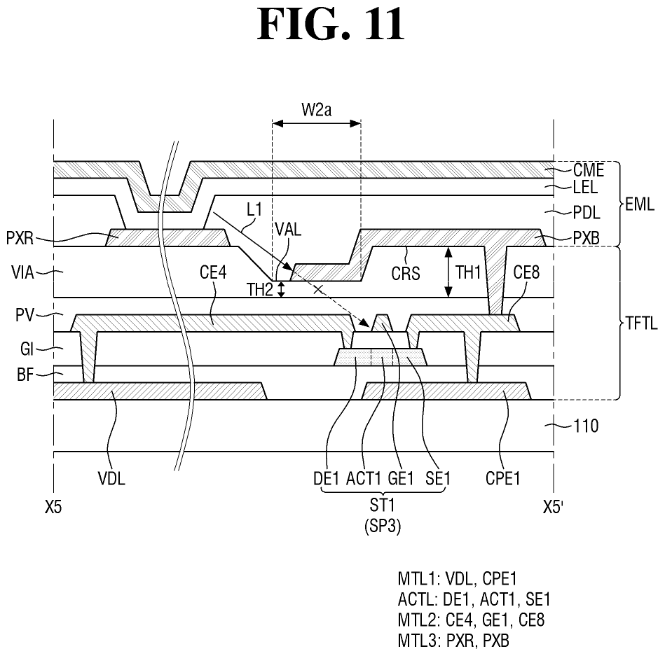

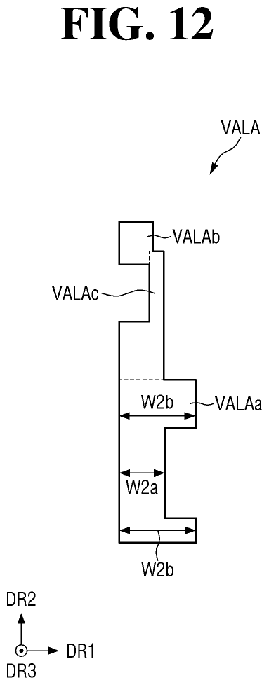

FIG. 10 is a layout diagram of a portion of a display panel according to another embodiment. FIG. 11 is a cross-sectional view taken along line X5-X5′ of FIG. 10. FIG. 12 is a plan view of a valley area in the layout of FIG. 10.

FIGS. 10 to 12 illustrate an embodiment that differs from the embodiment described above with reference to FIG. 4 and the like, in that the shape of the first region VALAa is different.

The embodiment of FIGS. 10 to 12 more specifically has a valley area VALA with a width W2a in the first direction DR1 of a part of the first region VALAa extending along the second direction DR2 that may be greater than the width W1a in the first direction DR1 of a part of the first region VALAa extending along the second direction DR2 in the embodiment described above with reference to FIG. 9. For example, in FIGS. 10 to 12, a width W2b in the first direction DR1 of a part of the first region VALAa extending along the first direction DR1 may be 1.5 to 2 times the width W2a in the first direction DR1 of a part of the first region VALAa extending along the second direction DR2.

The first region VALAa may overlap at least a part of the first transistor ST1 of the third pixel SP3 in the third direction DR3. For example, the first region VALAa may overlap the first drain electrode DE1 of the first transistor ST1 of the third pixel SP3 in the third direction DR3.

Comparing the embodiment of FIG. 11 to the embodiment of FIG. 6, more of the third pixel electrode PXB may be disposed on the valley VAL of FIG. 11 than in the embodiment described above with reference to FIG. 6 and the like. Accordingly, the light L1 emitted at a downward angle from the light emitting layer LEL disposed on the first pixel electrode PXR may be further prevented from being incident on the active layer ACTL of the first transistor ST1 of the third pixel SP3. Therefore, light induced degradation of the first transistor ST1 may be further reduced or minimized.

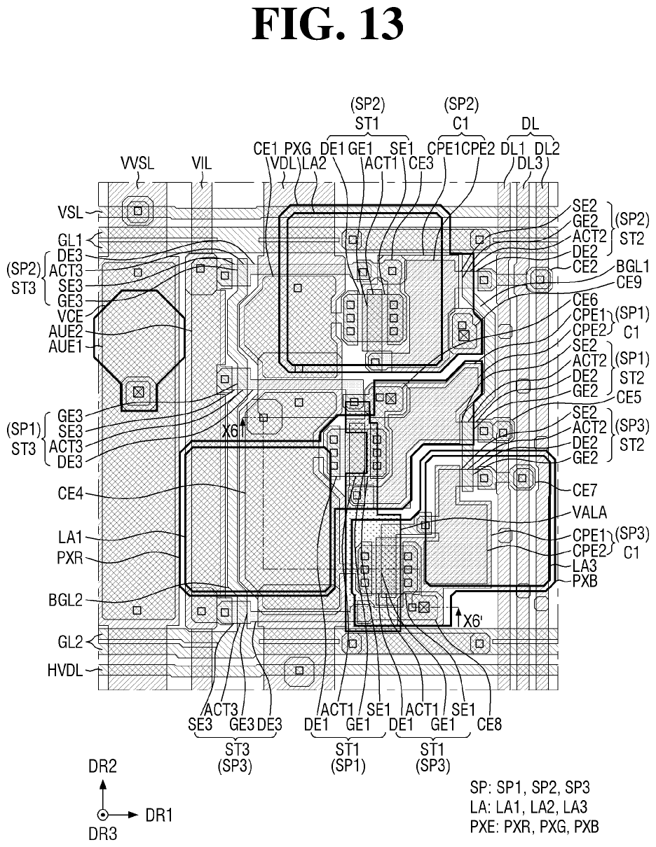

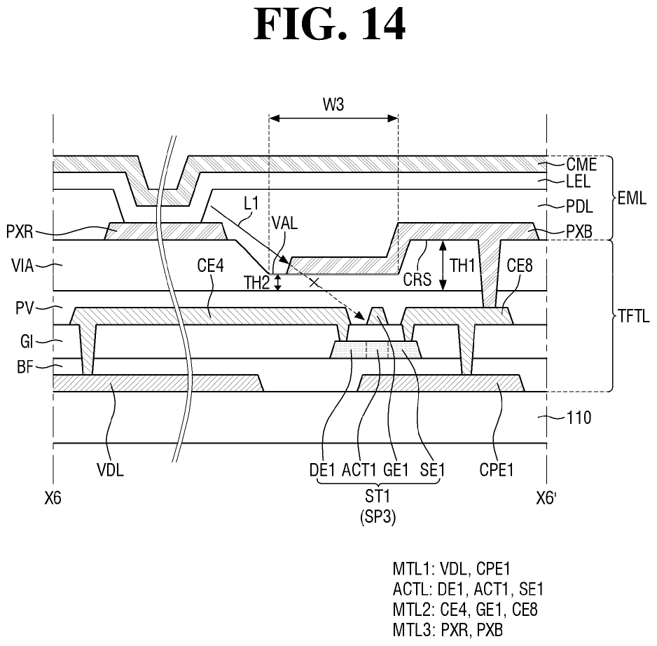

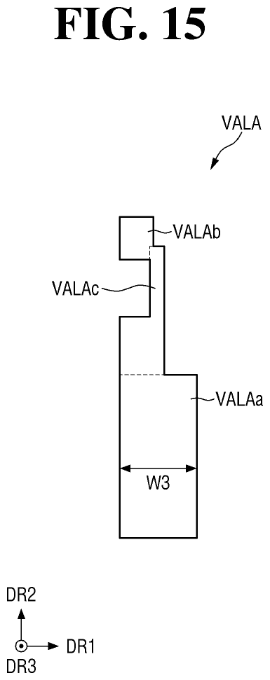

FIG. 13 is a layout diagram of a portion of a display panel according to another embodiment. FIG. 14 is a cross-sectional view taken along line X6-X6′ of FIG. 13. FIG. 15 is a plan view of a valley area according to still another embodiment.

The embodiment of FIGS. 13 to 15 primarily differs from the embodiments described above with reference to FIGS. 4 and 10 and the like, in that the shape of the first region VALAa of the valley area VALA is different.

More specifically, the first region VALAa as shown in FIG. 15 may have a rectangular shape. A width W3 of the first region VALAa in the first direction DR1 may be constant in the second direction DR2. For example, the width W3 of the first region VALAa in the first direction DR1 may be the same as the widths W1b and W2b in the first direction DR1 of a part of the first region VALAa extending along the first direction DR1 in the above-described embodiments.

The first region VALAa may overlap at least a part of the first transistor ST1 of the third pixel SP3 in the third direction DR3 as shown in FIG. 14. For example, the first region VALAa may overlap the first drain electrode DE1, the first active region ACT1, and the first gate electrode GE1 of the first transistor ST1 of the third pixel SP3 in plan view, i.e., when viewed along the third direction DR3.

In the embodiment of FIGS. 13 to 15, more of the third pixel electrode PXB may be disposed on the valley VAL than in the embodiments described above with reference to FIGS. 6 and 11 and the like. Accordingly, more of the third pixel electrode PXB may be disposed at a lower level to block the light L1 emitted at a downward angle from the light emitting layer LEL disposed on the first pixel electrode PXR, so that the light L1 may be further prevented from being incident on the active layer ACTL of the first transistor ST1 of the third pixel SP3. Therefore, light induced degradation of the first transistor ST1 may be further reduced or minimized.

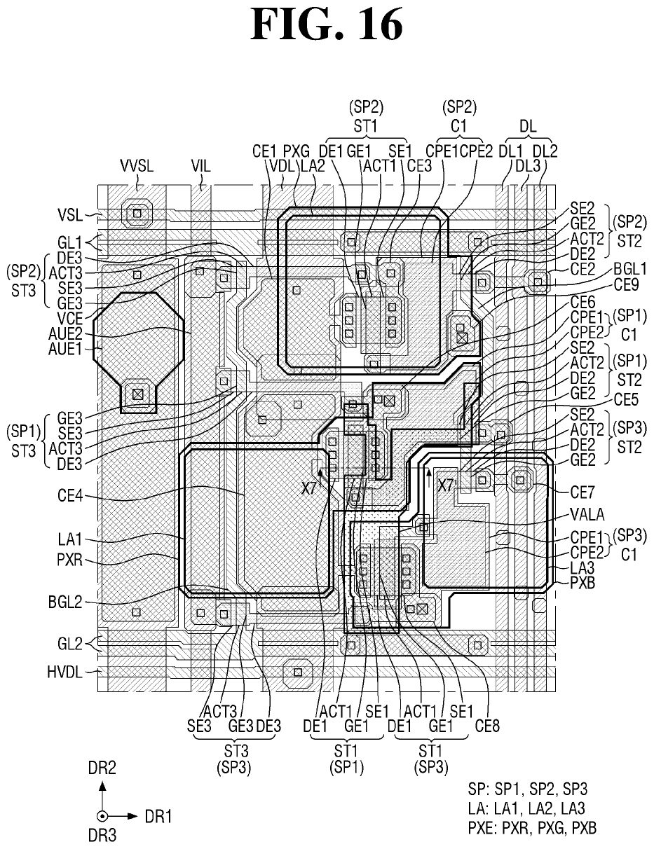

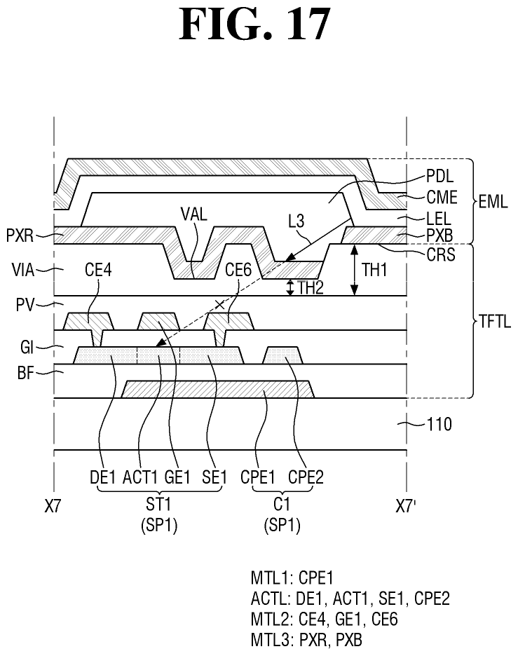

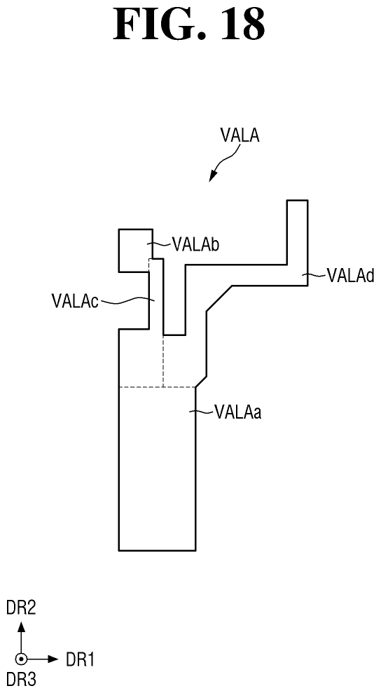

FIG. 16 is a layout diagram of a portion of a display panel according to still another embodiment. FIG. 17 is a cross-sectional view taken along line X7-X7′ of FIG. 16. FIG. 18 is a plan view of a valley area in the embodiment of FIG. 16.

The embodiment of FIGS. 16 to 18 differs from the embodiments described above with reference to FIGS. 4, 10, and 13 and the like, in that the valley area VALA as shown in FIG. 18 further includes a fourth region VALAd. More specifically, the valley area VALA may further include the fourth region VALAd.

The fourth region VALAd may protrude from the first region VALAa and the third region VALAc in a generally diagonal direction between the first and second directions DR1 and DR2 in plan view. The fourth region VALAd may be disposed between the first pixel electrode PXR and the third pixel electrode PXB in plan view. For example, the fourth region VALAd may be disposed between the third pixel electrode PXB and the first transistor ST1 of the first pixel SP1 in plan view.

The fourth region VALAd may be disposed to surround at least a part of the first transistor ST1 of the first pixel SP1 in plan view. The fourth region VALAd may be disposed particularly to surround a side of the first transistor ST1 of the first pixel SP1 facing the third pixel electrode PXB in plan view.

The fourth region VALAd may overlap the first capacitor C1 of the first pixel SP1 in plan view, i.e., when viewed along the third direction DR3. The shape of the fourth region VALAd may correspond to the shape of the end of the first capacitor C1 of the first pixel SP1 facing the third pixel electrode PXB in plan view.

In the embodiment of FIGS. 16 to 18, the first pixel electrode PXR may block light L3 emitted at a downward angle from the light emitting layer LEL disposed on the third pixel electrode PXB and may prevent the light L3 from being incident on the active layer ACTL of the first transistor ST1 of the first pixel SP1. Therefore, light induced degradation of the first transistor ST1 may be reduced or minimized.

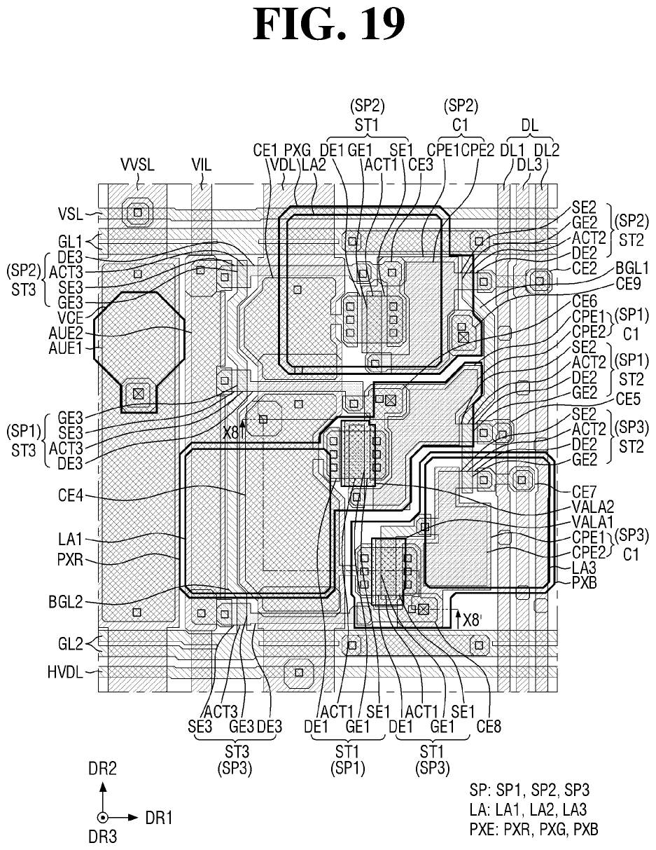

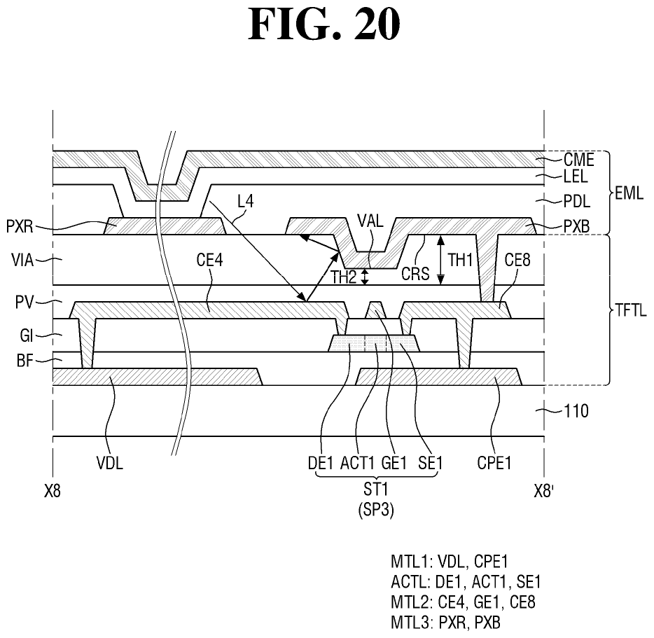

FIG. 19 is a layout diagram of a portion of a display panel according to another embodiment. FIG. 20 is a cross-sectional view taken along line X8-X8′ of FIG. 19.

The embodiment of FIGS. 19 and 20 differs from the embodiments described above with reference to FIGS. 4, 10, 13, and 16 and the like, in that the valley area VALA does not overlap the end of the pixel electrode PXE but overlaps the gate electrode of the transistor being protected and a portion of the pixel electrode overlying the gate electrode. In the specific example of FIG. 20, the valley area VALA overlaps the first gate electrode GE1 and the first active region ACT1 of the first transistor ST1 of the third pixel SP3, and the third pixel electrode PXB extends into and through the valley area VALA with an end of the third pixel electrode being back on the crest CRS.

The valley area VALA of FIGS. 19 and 20 may include a first valley area VALA1 and a second valley area VALA2 shown in FIG. 19.

The first valley area VALA1 may overlap the first gate electrode GE1 and the first active region of the first transistor ST1 of the third pixel SP3. The first valley area VALA1 may not overlap the end of the third pixel electrode PXB.

The second valley area VALA2 may overlap the first gate electrode GE1 and the first active region ACT1 of the first transistor ST1 of the first pixel SP1. The second valley area VALA2 may not overlap the end of the first pixel electrode PXR.

As shown in FIG. 20, one end of the third pixel electrode PXB facing the first pixel electrode PXR may be positioned at the same height as the first pixel electrode PXR, i.e., on the crest CRS of the via layer VIA. However, a portion of the third pixel electrode PXB overlapping the first gate electrode GE1 of the first transistor ST1 may be positioned at a lower height than the first pixel electrode PXR, i.e., on the valley VAL of the via layer VIA.

FIG. 20 shows light LA emitted at a downward angle from the light emitting layer LEL disposed on the first pixel electrode PXR may be reflected by the fourth connection electrode CE4 of the second metal layer MTL2 and proceed toward the bottom surface of the third pixel electrode PXB. The light LA reflected by the fourth connection electrode CE4 may subsequently be reflected from an inclined surface of the third pixel electrode PXB, which is located on the slope between the crest CRS and the valley VAL of the via layer VIA. The light reflected from the inclined surface may then travel away from the first transistor ST1 of the third pixel SP3. Accordingly, some light LA of the light emitted from the light emitting layer LEL disposed on the first pixel electrode PXR may be prevented from being incident on the active layer ACTL of the first transistor ST1 of the third pixel SP3. Therefore, light induced degradation of the first transistor ST1 may be reduced or minimized.

In FIG. 20, only the first valley area VALA1 is illustrated, but the same principles may be applied to the second valley area VALA2, so the illustration and description of the second valley area VALA2 will be omitted.

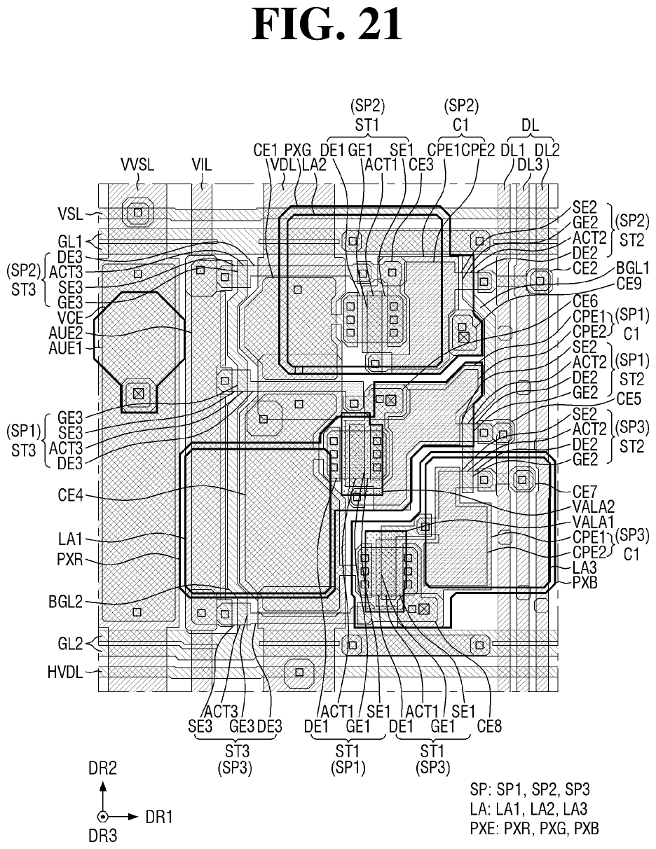

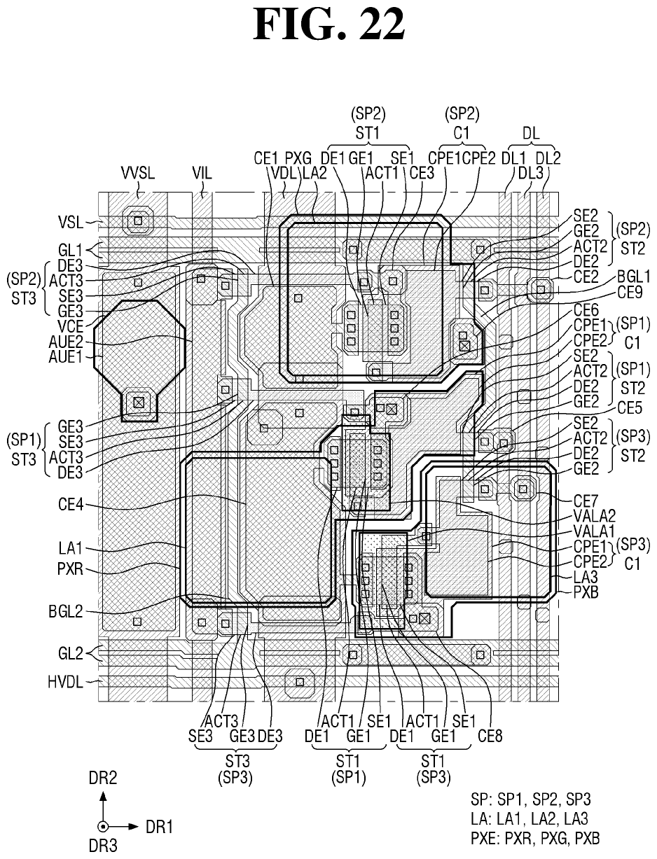

FIG. 21 is a layout diagram of a display panel according to another embodiment. FIG. 22 is a layout diagram of a display panel according to another embodiment. The embodiments of FIGS. 21 and 22 may be similar to the embodiment of FIGS. 19 and 20, but as shown in FIGS. 21 and 22, the widths of the valley area VALA in the first and second directions DR1 and DR2 may be different. For example, as shown in FIGS. 21 and 22, the widths of the valley area VALA in the first and second directions DR1 and DR2 may be larger than those in FIG. 19.

In one embodiment, as the width of the valley area VALA in the first direction DR1 increases, the valley area VALA may also overlap the first drain electrode DE1 and the first source electrode SE1 of the first transistor ST1 of each of the first pixel SP1 and the third pixel SP3 in the third direction DR3.

In one embodiment, as the width of the valley area VALA in the second direction DR2 increases, the first valley area VALA1 may overlap the eighth connection electrode CE8, and the second valley area VALA2 may overlap the sixth connection electrode CE6.

In concluding the detailed description, those skilled in the art will appreciate that many variations and modifications can be made to the preferred embodiments without departing from the principles of the present disclosure. Therefore, the disclosed embodiments of the invention are used in a generic and descriptive sense only and not for purposes of limitation.

What is claimed is:

1. A display device comprising a first pixel and a second pixel, wherein
the first pixel and the second pixel each comprises:
a first transistor;
a portion of a via layer disposed on the first transistor; and
a portion of a first metal layer disposed on the via layer,
the first pixel further comprises a first pixel electrode disposed in the first metal layer,
the second pixel further comprises a second pixel electrode disposed in the first metal layer, and
the first pixel electrode has a first end that faces the second pixel electrode and is positioned at a height lower than the second pixel electrode.

2. The display device of claim 1, wherein
the via layer comprises a crest and a valley,
a thickness of the crest is greater than a thickness of the valley,
the first end is positioned on the valley, and
the second pixel electrode is positioned on the crest.

3. The display device of claim 2, wherein the thickness of the crest is 3 to 5 times the thickness of the valley.

4. The display device of claim 2, wherein
the via layer comprises a valley area, which is an area where the valley is positioned, and
the valley area is disposed between the first transistor of the first pixel and the second pixel electrode in plan view.

5. The display device of claim 4, further comprising a pixel defining layer disposed on the first metal layer, wherein
the pixel defining layer comprises a plurality of open portions overlapping at least a part of the first pixel electrode and the second pixel electrode, and
the open portions do not overlap the valley area.

6. The display device of claim 5, wherein the open portions are disposed on the crest.

7. The display device of claim 4, wherein the valley area is disposed to surround at least a portion of the first transistor of the first pixel in plan view.

8. The display device of claim 7, wherein the valley area is disposed to surround a side of the first transistor of the first pixel in plan view, the side facing the second pixel electrode.

9. The display device of claim 4, further comprising a third pixel, wherein
the third pixel further comprises a third pixel electrode disposed in the first metal layer, and
a second end, which is an end of the second pixel electrode, facing the third pixel electrode, is positioned at a height lower than the third pixel electrode.

10. The display device of claim 9, wherein the valley area comprises:
a first region overlapping the first end;
a second region overlapping the second end; and
a third region connecting the first region to the second region.

11. The display device of claim 10, wherein the first region is disposed to surround a side of the first transistor of the first pixel in plan view, the side facing the second pixel electrode.

12. The display device of claim 10, wherein the second region is disposed between the third pixel electrode and a side of the first transistor of the second pixel in plan view, the side facing the third pixel electrode.

13. The display device of claim 10, wherein the third region is disposed to surround a side of the first transistor of the second pixel in plan view, the side facing the first pixel electrode.

14. The display device of claim 10, wherein the first region overlaps the first transistor of the first pixel.

15. The display device of claim 10, wherein
the valley area further comprises a fourth region protruding from the third region, and
the fourth region is disposed between the first pixel electrode and the first transistor of the second pixel in plan view.

16. The display device of claim 2, wherein
each of the first pixel and the second pixel further comprises a first capacitor connected to the first transistor, and
the first capacitor of each of the first pixel and the second pixel overlaps the crest.

17. The display device of claim 1, wherein in a thickness direction of the via layer, no other metal layer is disposed between the first metal layer and the first transistor of the first pixel.

18. The display device of claim 1, each of the first pixel and the second pixel further comprising:
a light emitting layer disposed on the first metal layer; and
a second metal layer disposed on the light emitting layer,
wherein the first transistor is a driving transistor configured to drive light emission of the light emitting layer.

19. A display device comprising a first pixel and a second pixel, wherein
the first pixel and the second pixel each comprises:
a first transistor;
a portion of a via layer disposed on the first transistor; and
a portion of a first metal layer disposed on the via layer,
the first pixel further comprises a first pixel electrode disposed in the first metal layer,
the second pixel further comprises a second pixel electrode disposed in the first metal layer, and
a portion of the first pixel electrode overlapping the first transistor of the first pixel is positioned at a height lower than the second pixel electrode.

20. The display device of claim 19, wherein a first end of the first pixel electrode facing the second pixel electrode is positioned at the same height as the second pixel electrode.

21. The display device of claim 19, wherein
the via layer comprises a crest and a valley,
a thickness of the crest is greater than a thickness of the valley,
a portion of the first pixel electrode overlapping the first transistor of the first pixel is positioned on the valley, and
the second pixel electrode is positioned on the crest.

22. The display device of claim 19, wherein in a thickness direction of the via layer, no other metal layer is disposed between the first metal layer and the first transistor of the first pixel.
